(19) United States
(12) Patent Application Publication
(10) Pub. No.: US 2024/0396547 A1
(43) Pub. Date: Nov. 28, 2024

(54) CIRCUIT STRUCTURE AND DEVICE

(71) Applicant: Shanghai Tianma Microelectronics Co., Ltd., Shanghai (CN)

(72) Inventors: Kaidi ZHANG, Shanghai (CN); Baiquan LIN, Shanghai (CN); Liying WANG, Shanghai (CN); Dongli ZHANG, Shanghai (CN); Linzhi WANG, Shanghai (CN); Ping SU, Shanghai (CN); Kerui XI, Shanghai (CN)

(73) Assignee: Shanghai Tianma Microelectronics Co., Ltd., Shanghai (CN)

(21) Appl. No.: 18/797,110

(22) Filed: Aug. 7, 2024

(30) Foreign Application Priority Data
Feb. 23, 2024 (CN) 202410205736.6

(51) Int. Cl. H03K 17/687

(52) U.S. Cl. CPC H03K 17/687

(57) ABSTRACT

Provided circuit structure includes a first voltage division branch and a second voltage division branch. The first voltage division branch includes a first control terminal and a first voltage division output terminal, and the second voltage division branch includes a second control terminal and a second voltage division output terminal. The first control terminal of the first voltage division branch receives a first initial signal V0, and the first voltage division output terminal is electrically connected to the second control terminal of the second voltage division branch. At a first pulse level stage, the second voltage division output terminal outputs a first output level signal, and at a second pulse level stage, the second voltage division output terminal outputs a second output level signal different from the first output level signal.

### CROSS-REFERENCE TO RELATED APPLICATION(S)

This application claims priority to Chinese Patent Application No. 202410205736.6 filed Feb. 23, 2024, the disclosure of which is incorporated herein by reference in its entirety.

### TECHNICAL FIELD

Embodiments of the present disclosure relate to the technical field of circuit design and, in particular, to a circuit structure and a device.

### BACKGROUND

In the related art, a dedicated driver chip is generally designed for an electronic device based on a driving principle and driving process of the electronic device, to provide an adapted drive signal to the electronic device, to implement the driving process. However, the driver chip cannot meet actual driving requirements due to changes in application scenarios or changes in application fields. For example, when the drive voltage required is too low, the dedicated driver chip needs to be redesigned and remanufactured, resulting in relatively high design difficulty and cost increase in the material and time.

### SUMMARY

Embodiments of the present disclosure provide a circuit structure. The circuit structure includes a first voltage division branch and a second voltage division branch. A first terminal of the first voltage division branch receives a first power signal V1, a second terminal of the first voltage division branch receives a second power signal V2, a first terminal of the second voltage division branch receives a third power signal V3, and a second terminal of the second voltage division branch receives a fourth power signal V4, where V1>V2, and V3>V4. The first voltage division branch includes a first control terminal and a first voltage division output terminal, and the second voltage division branch includes a second control terminal and a second voltage division output terminal. The first control terminal receives a first initial signal V0, and the first voltage division output terminal is electrically connected to the second control terminal. The first initial signal V0 includes a first pulse level stage and a second pulse level stage. The first voltage division branch and the second voltage division branch are configured to perform the following operations: at the first pulse level stage, the second voltage division output terminal outputs a first output level signal under control of an output signal of the first voltage division output terminal; and at the second pulse level stage, the second voltage division output terminal outputs a second output level signal under the control of the output signal of the first voltage division output terminal. The first output level signal and the second output level signal are different.

Embodiments of the present disclosure further provide a device. The device includes a circuit structure. The circuit structure includes a first voltage division branch and a second voltage division branch. A first terminal of the first voltage division branch receives a first power signal V1, a second terminal of the first voltage division branch receives a second power signal V2, a first terminal of the second voltage division branch receives a third power signal V3, and a second terminal of the second voltage division branch receives a fourth power signal V4, where V1>V2, and V3>V4. The first voltage division branch includes a first control terminal and a first voltage division output terminal, and the second voltage division branch includes a second control terminal and a second voltage division output terminal. The first control terminal receives a first initial signal V0, and the first voltage division output terminal is electrically connected to the second control terminal. The first initial signal V0 includes a first pulse level stage and a second pulse level stage. The first voltage division branch and the second voltage division branch are configured to perform the following operations: at the first pulse level stage, the second voltage division output terminal outputs a first output level signal under control of an output signal of the first voltage division output terminal; and at the second pulse level stage, the second voltage division output terminal outputs a second output level signal under the control of the output signal of the first voltage division output terminal. The first output level signal and the second output level signal are different.

### BRIEF DESCRIPTION OF DRAWINGS

FIG. 1 is a structure diagram of a circuit structure according to an embodiment of the present disclosure.

FIG. 2 is a signal timing diagram of the circuit structure shown in FIG. 1.

FIG. 3 is another structure diagram of a circuit structure according to an embodiment of the present disclosure.

FIG. 4 is another structure diagram of a circuit structure according to an embodiment of the present disclosure.

FIG. 5 is another structure diagram of a circuit structure according to an embodiment of the present disclosure.

FIG. 6 is another structure diagram of a circuit structure according to an embodiment of the present disclosure.

FIG. 7 is another structure diagram of a circuit structure according to an embodiment of the present disclosure.

FIG. 8 is a signal timing diagram of the circuit structure shown in FIG. 4.

FIG. 9 is a signal timing diagram of the circuit structure shown in FIG. 7.

FIG. 10 is another structure diagram of a circuit structure according to an embodiment of the present disclosure.

FIG. 11 is another structure diagram of a circuit structure according to an embodiment of the present disclosure.

FIG. 12 is a signal timing diagram of the circuit structure shown in FIG. 11.

FIG. 13 is another structure diagram of a circuit structure according to an embodiment of the present disclosure.

FIG. 14 is a signal timing diagram of the circuit structure shown in FIG. 13.

FIG. 15 is another structure diagram of a circuit structure according to an embodiment of the present disclosure.

FIG. 16 is another structure diagram of a circuit structure according to an embodiment of the present disclosure.

FIG. 17 is another structure diagram of a circuit structure according to an embodiment of the present disclosure.

FIG. 18 is a layout diagram of the circuit structure shown in FIG. 13.

FIG. 19 is a structure diagram of a film in the circuit structure shown in FIG. 18.

FIG. 20 is a structure diagram of another film in the circuit structure shown in FIG. 18.

FIG. 21 is a structure diagram of yet another film in the circuit structure shown in FIG. 18.

FIG. 22 is a section view of the circuit structure shown in FIG. 10.

FIG. 23 is a structure diagram of a device according to an embodiment of the present disclosure.

FIG. 24 is a structure diagram of electrowetting technology according to an embodiment of the present disclosure.

FIG. 25 is a section view of a single pixel in a digital microfluidic device according to an embodiment of the present disclosure.

FIG. 26 is a section view of an electronic-paper display device according to an embodiment of the present disclosure.

FIG. 27 is a structure diagram of a driver circuit according to an embodiment of the present disclosure.

FIG. 28 is a structure diagram of another driver circuit according to an embodiment of the present disclosure.

### DETAILED DESCRIPTION

The present disclosure is further described in detail below in conjunction with drawings and embodiments. It is to be understood that the embodiments described here are intended to illustrate the present disclosure and not to limit the present disclosure. Additionally, it is to be noted that for ease of description, only part, not all, of structures related to the present disclosure are illustrated in the drawings.

Terms used in the embodiments of the present disclosure are intended only to describe the specific embodiments and not to limit the present disclosure. It is to be noted that nouns of locality, including “up”, “down”, “left”, and “right” used in the embodiments of the present disclosure, are described from the perspective of the drawings and are not to be construed as a limitation to the embodiments of the present disclosure. In addition, in the context, it is to be understood that when a component is formed “on” or “below” another component, the component may not only be directly formed “on” or “below” another component but may also be indirectly formed “on” or “below” another component via an intermediate component. Terms such as “first” and “second” are used only for the purpose of description to distinguish between different components and not to indicate any order, quantity, or importance. For those of ordinary skill in the art, specific meanings of the preceding terms in the present disclosure may be understood based on specific situations.

The terms “comprise”, “include”, and variations thereof in the present disclosure are intended to be inclusive, that is, “including, but not limited to”. The term “based on” is “at least partially based on”. The term “an embodiment” refers to “at least one embodiment”.

It is to be noted that references to “first”, “second”, and the like in the present disclosure are merely intended to distinguish corresponding content and are not intended to limit an order or an interrelationship.

It is to be noted that “one” and “a plurality” mentioned in the present disclosure are illustrative and not limiting, and that those skilled in the art should understand that “one” and “a plurality” should be understood as “one or more” unless clearly indicated in the context.

For the problems mentioned in BACKGROUND, embodiments of the present disclosure provide a circuit structure. The circuit structure includes a first voltage division branch and a second voltage division branch. A first terminal of the first voltage division branch receives a first power signal V1, a second terminal of the first voltage division branch receives a second power signal V2, a first terminal of the second voltage division branch receives a third power signal V3, and a second terminal of the second voltage division branch receives a fourth power signal V4, where V1>V2, and V3>V4. The first voltage division branch includes a first control terminal and a first voltage division output terminal, and the second voltage division branch includes a second control terminal and a second voltage division output terminal. The first control terminal receives a first initial signal V0, and the first voltage division output terminal is electrically connected to the second control terminal.

The first initial signal V0 includes a first pulse level stage and a second pulse level stage. The first voltage division branch and the second voltage division branch are configured to perform the following operations: at the first pulse level stage, the second voltage division output terminal outputs a first output level signal under the control of an output signal of the first voltage division output terminal; and at the second pulse level stage, the second voltage division output terminal outputs a second output level signal under the control of the output signal of the first voltage division output terminal. The first output level signal and the second output level signal are different.

That the first voltage division branch and the second voltage division branch are disposed in the circuit structure and the first terminals and the second terminals of the first voltage division branch and the second voltage division branch receive two different power signals, respectively, so that the voltage division branch can selectively output the two different power signals received by the two terminals. The voltage value of the output signal is between the voltage values of the two different power signals due to the existence of voltage division. The first initial signal V0 received by the first control terminal of the first voltage division branch is used to select and control the voltage value of the output signal of the first voltage division branch. The second control terminal of the second voltage division branch is connected to the first output terminal of the first voltage division branch, so that the voltage value of the output signal of the second voltage division branch is selected and controlled according to the output signal of the first voltage division branch. In this manner, the first power signal V1 and the second power signal V2 that are received by the two terminals of the first voltage division branch are set reasonably so that the first voltage division branch can output signals with different voltage values in response to a change in the first initial signal V0. Further, the third power signal V3 and the fourth power signal V4 that are received by the two terminals of the second voltage division branch are set reasonably so that the second voltage division branch can output signals with different voltage values in response to the output signal of the first voltage division branch. In conclusion, by setting the above four types of power signals reasonably, especially the third power signal V3 and the fourth power signal V4, the second voltage division output terminal of the second voltage division branch can output two different level signals (that is, the first output level signal and the second output level signal) respectively, in response to the first pulse level stage and the second pulse level stage of the first initial signal V0. The circuit structure implements synchronization between the timing of the output signal and the timing of the first initial signal V0, and the level values of the output signals can be designed flexibly according to different power signals. In an example, when the voltage of the third power signal V3 is greater than the maximum voltage of the first initial signal V0 and the voltage of the fourth power signal V4 is less than the minimum voltage of the first initial signal V0, the circuit structure can output a first pulse level signal with a voltage value greater than the maximum voltage value of the first initial signal V0 at the first pulse level stage of the first initial signal V0 and output a second pulse level signal with a voltage value less than the minimum voltage value of the first initial signal V0 at the second pulse level stage of the first initial signal V0, thereby adjusting an amplitude range of the first initial signal V0.

In the above technical solution, amplitude range of the drive signal provided by an existing dedicated chip can be adjusted without changing the drive timing of the drive signal. In this manner, the driving performance of the drive signal is improved, and the existing dedicated chip can meet actual driving requirements in variety application scenarios or expanded application fields, thereby alleviating the problem of an insufficient drive capability of the existing dedicated chip and expanding the application scenarios and fields of the existing dedicated chip. In addition, the design and manufacture of a new chip can be avoided, or the design difficulty of the dedicated chip can be reduced, thereby contributing to saving a material cost and a time cost.

Solutions of the circuit structure and the device according to the present disclosure are described clearly and completely hereinafter in conjunction with drawings in embodiments of the present disclosure. Based on the embodiments of the present disclosure, all other embodiments obtained by those of ordinary skill in the art without any creative effort are within the scope of the present disclosure.

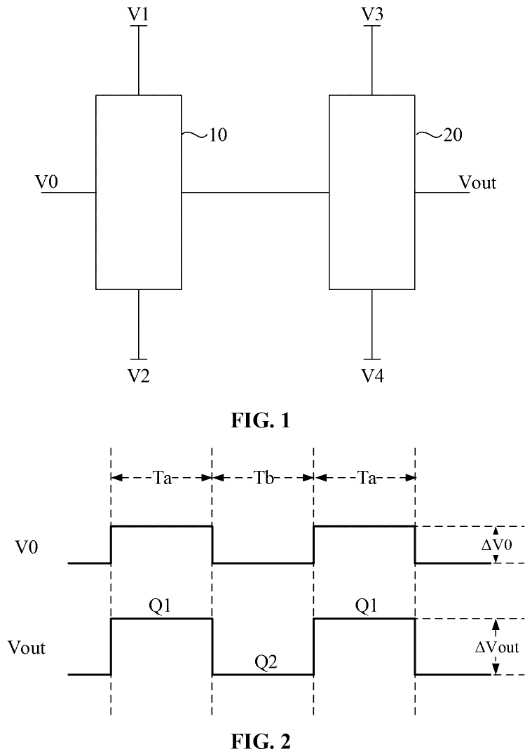

FIG. 1 is a structure diagram of a circuit structure according to an embodiment of the present disclosure, and FIG. 2 is a signal timing diagram of the circuit structure shown in FIG. 1. Referring to FIGS. 1 and 2, the circuit structure includes a first voltage division branch 10 and a second voltage division branch 20. A first terminal of the first voltage division branch 10 receives a first power signal V1, a second terminal of the first voltage division branch 10 receives a second power signal V2, a first terminal of the second voltage division branch 20 receives a third power signal V3, and a second terminal of the second voltage division branch 20 receives a fourth power signal V4, where V1>V2, and V3>V4. The first voltage division branch 10 includes a first control terminal and a first voltage division output terminal, and the second voltage division branch 20 includes a second control terminal and a second voltage division output terminal. The first control terminal receives a first initial signal V0, and the first voltage division output terminal is electrically connected to the second control terminal.

The first initial signal V0 includes a first pulse level stage Ta and a second pulse level stage Tb. The first voltage division branch 10 and the second voltage division branch 20 are configured to perform the following operations: at the first pulse level stage Ta, the second voltage division output terminal outputs a first output level signal Q1 under control of an output signal of the first voltage division output terminal; and at the second pulse level stage Tb, the second voltage division output terminal outputs a second output level signal Q2 under the control of the output signal of the first voltage division output terminal. The first output level signal Q1 and the second output level signal Q2 are different.

In one or more embodiments of the present disclosure, the first power signal V1, the second power signal V2, the third power signal V3, and the fourth power signal V4 may be positive values, negative values, or 0 based on that V1>V2 and V3>V4 are satisfied, that is, the four power signals may be any values based on that the above relationships are satisfied, which is not limited in the embodiments of the present disclosure. In an example, V1=12 V, V2=−5 V, V3=12 V, and V4=−5 V; in another example, V1=12 V, V2=0 V, V3=12 V, and V4=0 V; or, in another example, V1=5 V, V2=−5 V, V3=12 V, and V4=−12 V. As described above, the first initial signal V0 received by the first control terminal is used as a control signal of the first voltage division branch 10. The first voltage division branch 10 selectively outputs the first power signal V1 or the second power signal V2 according to different level values of the first initial signal V0 at different pulse level stages. Herein, V1>V2 indicates that the voltage of the output signal of the first voltage division branch 10 varies with the change of the first initial signal V0. The second control terminal is electrically connected to the first output terminal, and the output signal of the first voltage division branch 10 is used as a control signal of the second voltage division branch 20, and under the control of the output signal of the first voltage division branch 10, the second voltage division branch 20 selectively outputs the third power signal V3 or the fourth power signal V4 according to voltage values of the output signal of the first voltage division branch 10 at different stages. Similarly, V3>V4 indicates that the voltage of the output signal of the second voltage division branch 20 varies with the change of the output signal of the first voltage division branch 10. As can be seen from the timing of the first initial signal V0 and the output signal Vout of the second voltage division output terminal shown in an example in FIG. 2, at the first pulse level stage Ta, the output signal Vout (i.e., the first output level signal Q1) is output as a high-level signal, and at the second pulse level stage Tb, the output signal Vout (i.e., the second output level signal Q2) is output as a low-level signal. The circuit structure converts the first initial signal V0 which is input to the output signal Vout of the second voltage division output terminal. The output signal Vout of the second voltage division output terminal, that is, the output signal Vout of the circuit structure, is synchronized with the first initial signal V0 in timing. However, since an amplitude of the output signal Vout mainly depends on the power signal, the four power signals are set reasonably, especially the third power signal V3 and the fourth power signal V4, thereby controlling the amplitude of the voltage of the output signal Vout. As shown in the example in FIG. 2, a voltage difference ΔVout of the output signal Vout at different stages is significantly greater than a voltage difference ΔV0 of the first initial signal V0 at the different stages. In this manner, an amplitude of a level of the first initial signal V0 is adjusted by the circuit structure, and step-up adjustment shown in the example makes up for the problem of a relatively low voltage of the first initial signal V0.

As shown in FIG. 2, at the first pulse level stage Ta, the first initial signal V0 is a high-level signal, and the output signal Vout, that is, the first output level signal Q1, is also a high-level signal; at the second pulse level stage Tb, the first initial signal V0 is a low-level signal, and the output signal Vout, that is, the second output level signal Q2, is also a low-level signal. It is to be noted that the case is only an example of the present disclosure. Based on the first initial signal V0 determined (for example, at the first pulse level stage Ta, the first initial signal V0 is a high-level signal, and at the second pulse level stage Tb, the first initial signal V0 is a low-level signal), an output of the first voltage division output terminal or the second voltage division output terminal at the two pulse level stages mainly depends on the internal design of the first voltage division branch 10 or the second voltage division branch 20, which is not limited herein. The circuit design of the first voltage division branch 10 or the second voltage division branch 20 is not described in detail herein. For details, reference may be made later.

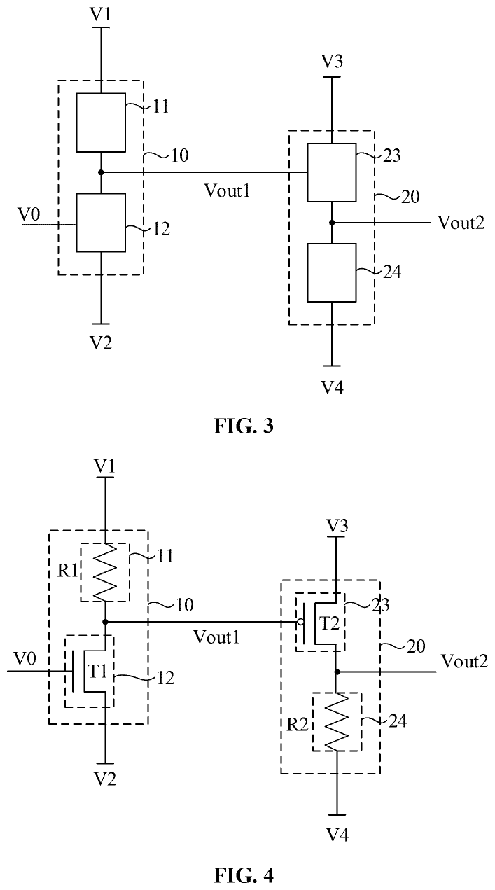

FIG. 3 is another structure diagram of a circuit structure according to an embodiment of the present disclosure. Referring to FIG. 3, in one or more embodiments, the first voltage division branch 10 includes a first voltage division unit 11 and a second voltage division unit 12, where a connection node between the first voltage division unit 11 and the second voltage division unit 12 is the first voltage division output terminal. The first voltage division unit 11 includes the first control terminal, and/or the second voltage division unit 12 includes the first control terminal.

The second voltage division branch 20 includes a third voltage division unit 23 and a fourth voltage division unit 24, where a connection node between the third voltage division unit 23, and the fourth voltage division unit 24 is the second voltage division output terminal. The third voltage division unit 23 includes the second control terminal, and/or the fourth voltage division unit 24 includes the second control terminal.

In the present embodiment, each voltage division branch is divided into two voltage division units, and a connection node between the two voltage division units is used as an output terminal of each voltage division branch. On the one hand, the voltage division unit plays a role of voltage division, that is, when the voltage division unit is turned on, the voltage drops. On the other hand, the voltage division unit plays the role of a switch, that is, the voltage division unit can be turned on through a corresponding level signal so that a power signal received by the voltage division unit can be transmitted to the output terminal. The second voltage division unit 12 in the first voltage division branch 10 is taken as an example. The second voltage division unit 12 may be turned on when the first initial signal V0 is at a preset pulse level stage and turned off when the first initial signal V0 is at another pulse level stage. For example, the first voltage division unit 11 is a normally open circuit, that is, the first voltage division unit 11 is always in the ON state. When the second voltage division unit 12 is turned on, the first power signal V1 is connected to the second power signal V2, and potential signals of the first power signal V1 and the second power signal V2 at the connection node between the first voltage division unit 11 and the second voltage division unit 12 are output by the first voltage division output terminal. When the second voltage division unit 12 is turned off, the first power signal V1 is connected to the first voltage division output terminal by the first voltage division unit 11, and a voltage signal is output by the first voltage division output terminal, and the voltage signal is obtained after voltage drop on the first power signal V1 by the first voltage division unit 11. As can be seen, the first voltage division branch 10 outputs different voltage signals at different pulse level stages of the first initial signal, thereby selecting and controlling the output signal of the first voltage division branch 10. Moreover, since the output signal mainly depends on the first power signal V1 and the second power signal V2, the first power signal V1 and the second power signal V2 can be set reasonably to adjust the voltage value of the output signal. Similarly, for the second voltage division branch 20, the third power signal V3 and the fourth power signal V4 are set reasonably, thereby adjusting the voltage value of the output signal of the second voltage division output terminal, that is, a voltage value of the output signal of the circuit structure.

As shown in FIG. 3, a control terminal of the second voltage division unit 12 is used as the first control terminal, the first voltage division unit 11 is a normally open circuit, a control terminal of the third voltage division unit 23 is used as the second control terminal, and the fourth voltage division unit 24 is a normally open circuit. It is to be added that the case is only an example of the present disclosure. It is to be understood that a control terminal of at least one of the first voltage division unit 11 and the second voltage division unit 12 should be used as the first control terminal to receive the first initial signal V0, and the first initial signal V0 can control at least one of the first voltage division unit 11 and the second voltage division unit 12 to be turned on or turned off to implement different outputs of the first voltage division branch 10. Similarly, a control terminal of at least one of the third voltage division unit 23 and the fourth voltage division unit 24 should be used as the second control terminal to receive the output signal of the first voltage division output terminal, and the output signal of the first voltage division output terminal can control at least one of the third voltage division unit 23 and the fourth voltage division unit 24 to be turned on or turned off to implement different outputs of the second voltage division branch 20.

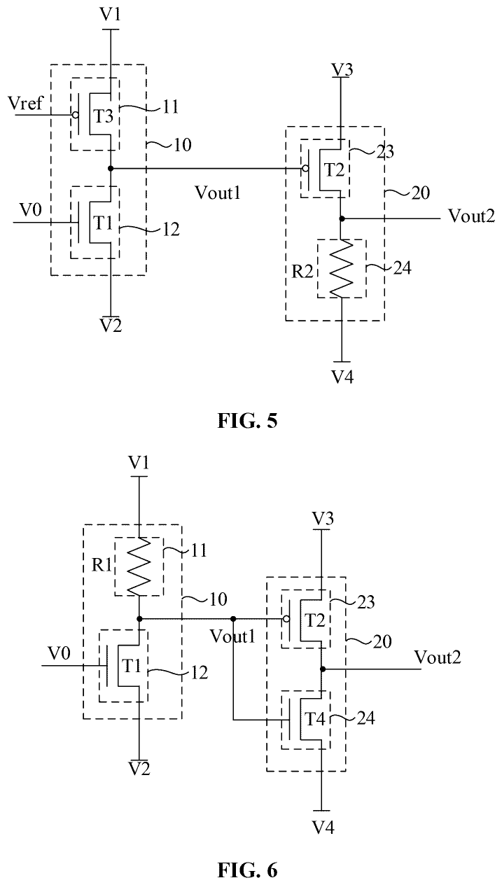

FIGS. 4 and 5 are another two structure diagrams of a circuit structure according to an embodiment of the present disclosure. Referring to FIGS. 4 and 5, in one or more embodiments, the first voltage division unit 11 includes a first resistor R1, and the second voltage division unit 12 includes a first transistor T1. A first terminal of the first resistor R1 receives the first power signal V1, a second terminal of the first resistor R1 is electrically connected to a first electrode of the first transistor T1, and a second electrode of the first transistor T1 receives the second power signal V2. As the first control terminal, a gate of the first transistor T1 receives the first initial signal V0.

Further, in one or more embodiments, the resistance of the first resistor R1 ranges from 10⁶Ω to 10⁸Ω, and/or the first transistor T1 is an N-type channel transistor.

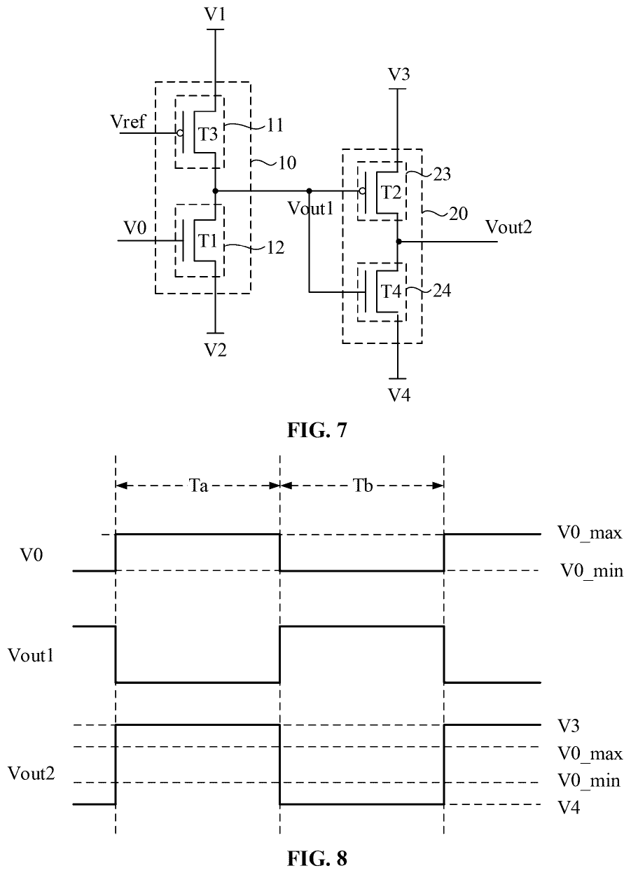

FIGS. 6 and 7 are another two structure diagrams of a circuit structure according to an embodiment of the present disclosure. Referring to FIGS. 6 and 7, in one or more embodiments, the first voltage division unit 11 includes a third transistor T3, and the second voltage division unit 12 includes a first transistor T1. A first electrode of the third transistor T3 receives the first power signal V1, a second electrode of the third transistor T3 is electrically connected to a first electrode of the first transistor T1, and a second electrode of the first transistor T1 receives the second power signal V2. A gate of the third transistor T3 receives a reference voltage signal Vref, and as the first control terminal, a gate of the first transistor T1 receives the first initial signal V0. A voltage of the reference voltage signal Vref is lower than a threshold voltage of the third transistor T3. The first transistor T1 and the third transistor T3 satisfy: R_{T1_on}<R_{T3}<R_{T1_off}, where R_{T1_on} is a resistance value of the first transistor T1 in an ON state, R_{T1_off} is a resistance value of the first transistor T1 in an OFF state, and R_{T3} is a resistance value of the third transistor T3 in a subthreshold state.

Further, in one or more embodiments, the first transistor is an N-type channel transistor, and the third transistor is a P-type channel transistor.

With continued reference to FIGS. 3 and 5, in one or more embodiments, the third voltage division unit 23 includes a second transistor T2, and the fourth voltage division unit 24 includes a second resistor R2. A first electrode of the second transistor T2 receives the third power signal V3, a second electrode of the second transistor T2 is electrically connected to a first terminal of the second resistor R2, and a second terminal of the second resistor R2 receives the fourth power signal V4. As the second control terminal, a gate of the second transistor T2 is electrically connected to the first voltage division output terminal.

Further, in one or more embodiments, the resistance of the second resistor R2 ranges from 10⁶Ω to 10⁸Ω, and/or the second transistor T2 is a P-type channel transistor.

With continued reference to FIGS. 4 and 6, in one or more embodiments, the third voltage division unit 23 includes a second transistor T2, and the fourth voltage division unit 24 includes a fourth transistor T4, where channel types of the second transistor T2 and the fourth transistor T4 are different. A first electrode of the second transistor T2 receives the third power signal V3, a second electrode of the second transistor T2 is electrically connected to a first electrode of a fourth transistor T4, and a second electrode of the fourth transistor T4 receives the fourth power signal V4. A gate of the second transistor T2 is electrically connected to a gate of the fourth transistor T4, and as the second control terminal, the gate of the second transistor T2 is electrically connected to the first voltage division output terminal.

Further, in one or more embodiments, the second transistor T2 is a P-type channel transistor, and the fourth transistor T4 is an N-type channel transistor.

In addition, in the circuit structure provided in one or more embodiments, V1≥V3, and V2≤V4.

For the above various circuit designs of the circuit structure, the driving processes and component selection of the circuit structure are explained and described below by using the circuit designs shown in FIGS. 4 and 7 as examples.

FIG. 8 is a signal timing diagram of the circuit structure shown in FIG. 4. Referring to FIGS. 4 and 8, as shown in an example in FIG. 4, the first transistor T1 is an N-type channel transistor, and the second transistor T2 is a P-type channel transistor. Moreover, In an example, V1>V2, and V3>V4. Further, V1≥V3, and V2≤V4.

Based on this, for the first voltage division branch 10, at the first pulse level stage Ta, In an example, the first initial signal V0 is a high-level signal. In this case, the gate of the first transistor T1 receives the high-level signal, and the first transistor T1 is turned on. An output voltage Vout1 of the first voltage division output terminal is R_{T1_on}×(V1−V2)/(R1+R_{T1_on})+V2, where R_{T1_on} is a resistance value of the first transistor T1 in an ON state. At the second pulse level stage Tb, In an example, the first initial signal V0 is a low-level signal. In this case, the gate of the first transistor T1 receives the low-level signal, and the first transistor T1 is turned off. The first voltage division output terminal directly receives the first power signal V1 through the first resistor R1, and the output voltage Vout1 is slightly lower than V1. As can be seen, the first voltage division output terminal implements two output voltages at the first pulse level stage Ta and the second pulse level stage Tb, respectively. In comparison, the first voltage division output terminal outputs a lower-level signal at the first pulse level stage Ta and outputs a higher-level signal at the second pulse level stage Tb.

Based on the output timing of the first voltage division branch 10, for the second voltage division branch 20, at the first pulse level stage Ta, the first voltage division output terminal outputs a low-level signal, the gate of the second transistor T2 receives the low-level signal, and the second transistor T2 is turned on. An output voltage Vout2 of the second voltage division output terminal is R2×(V3−V4)/(R2+R_{T2_on})+V4, where R_{T2_on} is a resistance value of the second transistor T2 in the ON state. At the second pulse level stage Tb, the first voltage division output terminal outputs a high-level signal, the gate of the second transistor T2 receives the high-level signal, and the second transistor T2 is turned off. The second voltage division output terminal directly receives the fourth power signal V4 through the second resistor R2, that is, the output voltage Vout2 is slightly lower than V4. As can be seen, the second voltage division output terminal implements two output voltages at the first pulse level stage Ta and the second pulse level stage Tb, respectively. In comparison, the second voltage division output terminal outputs a higher level signal at the first pulse level stage Ta and outputs a lower level signal at the second pulse level stage Tb.

As can be seen from the driving process of the above circuit structure, the output voltage Vout1 of the first voltage division output terminal, especially the output voltage at the second pulse level stage Tb, is related to the resistance value of the first resistor R1. In one or more embodiments of the present disclosure, the resistance of the first resistor R1 is set within a range of 10⁶Ωto 10⁸Ω, thereby ensuring that the first resistor R1 can control a current at the second pulse level stage Tb, avoiding excessive heat generated by the first resistor R1 and contributing to reducing the power consumption of the circuit structure. Similarly, the output voltage Vout2 of the second voltage division output terminal, especially the output voltage of the second pulse level stage Tb, is related to the resistance value of the second resistor R2. In one or more embodiments of the present disclosure, the resistance of the second resistor R2 is set within a range of 10⁶Ω to 10⁸Ω, thereby ensuring that the second resistor R2 can control a current at the second pulse level stage Tb, avoiding excessive heat generated by the second resistor R2 and contributing to reducing the power consumption of the circuit structure.

In addition, the resistance value of the first transistor T1 at the ON state and the resistance value of the first transistor T1 at the OFF state should differ by six orders of magnitude or more, for example, the resistance value at the ON state is 10⁴Ω, and the resistance value at the OFF state is 10¹⁰Ω. The resistance value of the first transistor T1 at the ON state should be set far less than the resistance value of the first resistor R1, and the resistance value of the first transistor T1 at the OFF state should be set far greater than the resistance value of the first resistor R1, for example, a difference of three orders of magnitude or more may be set. In this case, when the first transistor T1 is turned on, compared with the first resistor R1, the first transistor T1 is equivalent to a short circuit. In this case, the output signal of the first voltage division branch 10 is closer to the second power signal V2. When the first transistor T1 is turned off, compared with the first resistor R1, the first transistor T1 is equivalent to an open circuit. In this case, the output signal of the first voltage division branch 10 is closer to the first power signal V1.

Similarly, the resistance value of the second transistor T2 at the ON state and the resistance value of the second transistor T2 at the OFF state should differ by six orders of magnitude or more, for example, the resistance value at the ON state is 10⁴Ω, and the resistance value at the OFF state is 10¹⁰Ω. The resistance value of the second transistor T2 at the ON state should be set far less than the resistance value of the second resistor R2. The resistance value of the second transistor T2 at the OFF state should be set far greater than the resistance value of the second resistor R2, for example, a difference of three orders of magnitude or more may be set. In this case, when the second transistor T2 is turned on, compared with the second resistor R2, the second transistor T2 is equivalent to a short circuit. In this case, the output signal of the first voltage division branch 10 is closer to the third power signal V3. When the second transistor T2 is turned off, compared with the second resistor R2, the second transistor T2 is equivalent to an open circuit. In this case, the output signal of the second voltage division branch 20 is closer to the fourth power signal V4.

In addition, it is to be noted that the first transistor T1 is set as an N-type channel transistor, and the second transistor T2 is set as a P-type channel transistor. An object is to control high and low levels of the output signal of the second voltage division output terminal and high and low levels of the first initial signal V0 have the same phase, that is, the circuit structure only adjusts an amplitude of the voltage of the first initial signal V0, and the timing of the first initial signal V0 and a corresponding switch control logic based on the high and low levels are not changed. Of course, in some embodiments of the present disclosure, the channel types of the first transistor T1 and the second transistor T2 may also be switched. The first transistor T1 is a P-type channel transistor, and the second transistor is an N-type channel transistor. It can be inferred that the case can only adjust the amplitude of the voltage of the first initial signal V0 as well. In other embodiments of the present disclosure, the channel types of the first transistor T1, and the second transistor T2 may also be the same. It can also be inferred that in this case, the high and low levels of the output signal of the circuit structure and the high and low levels of the first initial signal V0 have inverse phases. Of course, both the circuit structure has the same phase compared with the high and low levels of the first initial signal V0, and the circuit structure has an inverse phase compared with the high and low levels of the first initial signal V0 can implement the same driving and only have opposite driving logics.

It also should be noted that a principle that reasonably setting the amplitudes of the third power signal V3 and the fourth power signal V4 can control the amplitudes of the output levels of the output signal Vout at different stages to implement the adjustment of the amplitude of the level of the first initial signal V0 is explained below by using the circuit structure shown in FIG. 4 as an example. In the circuit structure corresponding to FIGS. 4 and 8, for example, V3>V0_max, V4<V0_min, where V0_max refers to the maximum voltage value of the first initial signal V0 at different pulse level stages and may be understood as the voltage value of the first pulse level stage Ta, and V0_min refers to the minimum voltage value of the first initial signal V0 at different pulse level stages and may be understood as the voltage value of the second pulse level stage Tb. Therefore, the output signal Vout in the circuit structure is approximately V3 at the first pulse level stage Ta and is greater than the voltage value V0_max of the first initial signal V0 at the first pulse level stage Ta, and the output signal Vout in the circuit structure is approximately V4 at the second pulse level stage Tb and is less than the voltage value V0_min of the first initial signal V0 at the second pulse level stage Tb, thereby achieving an effect of step-up adjustment on the first initial signal V0 and making up for the problem of a relatively low voltage of the first initial signal V0. It may be understood that based on the first initial signal V0, by using the circuit structure, the third power signal V3 and the fourth power signal V4 are set reasonably, a signal that is synchronous in timing with the first initial signal V0 but different in amplitude with the first initial signal V0 can be output.

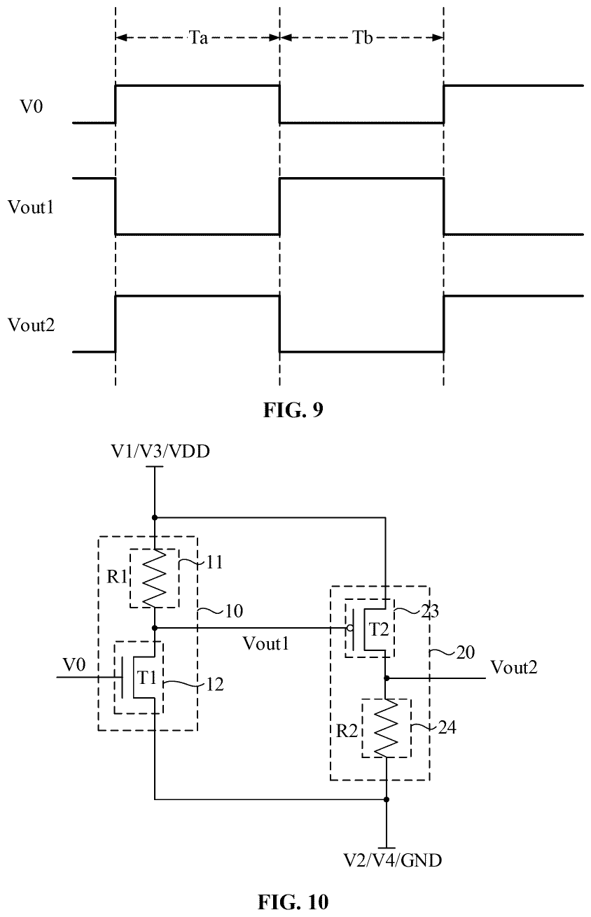

FIG. 9 is a signal timing diagram of the circuit structure shown in FIG. 7. Referring to FIGS. 7 and 9, as shown in an example in FIG. 7, the first transistor T1 is an N-type channel transistor, the third transistor T3 is a P-type channel transistor, the second transistor T2 is a P-type channel transistor, and the fourth transistor T4 is an N-type channel transistor. Moreover, for example, V1>V2, and V3>V4. Further, V1≥V3, and V2≤V4. Since the gate of the third transistor T3 receives the reference voltage signal Vref and the voltage of the reference voltage signal Vref is lower than the threshold voltage of the third transistor T3, the third transistor T3 is in the subthreshold state and may be equivalent to a resistor with a fixed resistance value. To facilitate understanding the action of the third transistor T3 herein, one or more embodiments of the present disclosure provides the following additional description on a subthreshold state of a transistor. The subthreshold state of the transistor refers to a working state of the transistor working at a subthreshold voltage. When the transistor is in a normal working state, an input gate voltage (Vgs) needs to be increased to a threshold voltage (Vt) or more so that the transistor is normally turned on, that is, the transistor enters a saturated state. In the subthreshold state, Vgs of the transistor is relatively low and cannot reach Vt completely, that is, Vgs<Vt, which means that no conductive channel is formed in the transistor. However, in practical application, even if Vgs<Vt, the transistor generates some faint leakage currents due to the diffusion of a few carriers near a surface. The magnitude of the current is generally small and is too small to enable a metal-oxide-semiconductor field-effect transistor (MOSFET) to be turned on, but the current is large enough to respond to the gate voltage, thereby controlling a circuit. In one or more embodiments of the present disclosure, the reference voltage signal Vref with a voltage less than the threshold voltage is provided at the gate of the third transistor T3 so that the third transistor T3 is in the subthreshold state, thereby controlling the connection between the first power signal V1 and the first voltage division output terminal. Moreover, an object of reducing power consumption can be achieved due to a relatively small current, that is, the connection between the first power signal V1 and the first voltage division output terminal may be equivalent to a resistor with a relatively large resistance value.

Based on this, for the first voltage division branch 10, at the first pulse level stage Ta, for example, the first initial signal V0 is a high-level signal. In this case, the gate of the first transistor T1 receives the high-level signal, and the first transistor T1 is turned on. In this case, an output voltage Vout1 of the first voltage division output terminal is R_{T1_on}×(V1−V2)/(R_{T3}+R_{T1_on})+V2, where R_{T1_on} is the resistance value of the first transistor T1 at the ON state, and R_{T3} is the resistance measured when the third transistor T3 is in the subthreshold state. At the second pulse level stage Tb, for example, the first initial signal V0 is a low-level signal. In this case, the gate of the first transistor T1 receives the low-level signal, and the first transistor T1 is turned off. The first voltage division output terminal directly receives the first power signal V1 through the third transistor T3, and the output voltage Vout1 is slightly lower than V1. As can be seen, the first voltage division output terminal implements two output voltages at the first pulse level stage Ta and the second pulse level stage Tb, respectively. In comparison, the first voltage division output terminal outputs a lower level signal at the first pulse level stage Ta and outputs a higher level signal at the second pulse level stage Tb.

Based on the output timing of the first voltage division branch 10, for the second voltage division branch 20, at the first pulse level stage Ta, the first voltage division output terminal outputs a low-level signal, both a gate of the second transistor T2 and a gate of the fourth transistor T4 receive the low-level signal, the second transistor T2 is turned on, and the fourth transistor T4 is turned off. The second voltage division output terminal directly receives the third power signal V3 through the second transistor T2, and an output voltage Vout2 is slightly lower than V3. At the second pulse level stage Tb, the first voltage division output terminal outputs a high-level signal, both the gate of the second transistor T2 and the gate of the fourth transistor T4 receive the high-level signal, the second transistor T2 is turned off, and the fourth transistor T4 is turned on. The second voltage division output terminal directly receives the fourth power signal V4 through the fourth transistor T4, and the output voltage Vout2 is slightly lower than V4. As can be seen, the second voltage division output terminal implements two output voltages at the first pulse level stage Ta and the second pulse level stage Tb, respectively. In comparison, the second voltage division output terminal outputs a higher level signal at the first pulse level stage Ta and outputs a lower level signal at the second pulse level stage Tb.

In the preceding embodiments, the first transistor T1 and the third transistor T3 satisfy: R_{T1_on}<R_{T3}<R_{T1_off}. Moreover, R_{T1_on} may be far less than R_{T3}, and a difference between R_{T1_on} and R_{T3} is three orders of magnitude or more; R_{T3} may be far less than R_{T1_off}, and a difference between R_{T3} and R_{T1_off} is three orders of magnitude or more. In this case, when the first transistor T1 is turned on, compared with the third transistor T3, the first transistor T1 is equivalent to a short circuit. In this case, the output signal of the first voltage division branch 10 is closer to the second power signal V2. When the first transistor T1 is turned off, compared with the third transistor T3, the first transistor T1 is equivalent to an open circuit. In this case, the output signal of the first voltage division branch 10 is closer to the first power signal V1.

As shown in FIG. 7, the first transistor T1 is an N-type channel transistor, the third transistor T3 is a P-type channel transistor, the second transistor T2 is a P-type channel transistor, and the fourth transistor T4 is an N-type channel transistor. It is also to be added that the case is only an example. The channel types of the first transistor T1 and the third transistor T3 may be different or the same. The first transistor T1 may also be a P-type channel transistor, and the third transistor T3 may also be an N-type channel transistor. Under the premise of different channel types, the second transistor T2 may also be a P-type channel transistor, and the fourth transistor T4 may also be an N-type channel transistor.

Regarding the working process and working principle of the circuit structure shown in FIGS. 5 and 6, reference can be made to that of the circuit structure shown in FIGS. 4 and 7, which are not repeated herein. Moreover, it is to be understood that the channel types of the related transistors in FIGS. 5 and 6 are only examples, and the transistors may be selected and replaced with reference to the transistors in FIGS. 4 and 7, which are not limited herein.

It also should be noted that in all the preceding embodiments of the circuit structure, voltage values of the first power signal V1, the second power signal V2, the third power signal V3, and the fourth power signal V4 need to be designed and selected according to practical requirements of the circuit structures. When the four power signals satisfy the above magnitude relationships, that is, V1>V2, V3>V4, V1≥V3, and V2≤V4, values of the four power signals may be positive values or negative values, which are not limited herein. In an example, V1 and V3 may be voltage drain drain (VDD) signals, and V2 and V4 may be voltage emitter emitter (VEE) signals.

FIG. 10 is another structure diagram of a circuit structure according to an embodiment of the present disclosure. Referring to FIG. 10, in some embodiments of the present disclosure, V1=V3, and V2=V4. In this case, only two power signals are needed to control the first voltage division branch 10 and the second voltage division branch 20, thereby reducing power supply wiring and simplifying the circuit structure. For example, V1 and V3 may be VDD signals and V2 and V4 may be ground (GND) signals. Herein, the first power signal V1, the second power signal V2, the third power signal V3, and the fourth power signal V4 in the circuit structure are described by taking the circuit structure shown in FIG. 4 as an example. In FIGS. 5 to 7 and a circuit structure not shown as an example, in one or more embodiments, the first power signal V1 and the third power signal V3 may also be the same and may be a VDD signal, and the second power signal V2 and the fourth power signal V4 may also be the same and may be a GND signal.

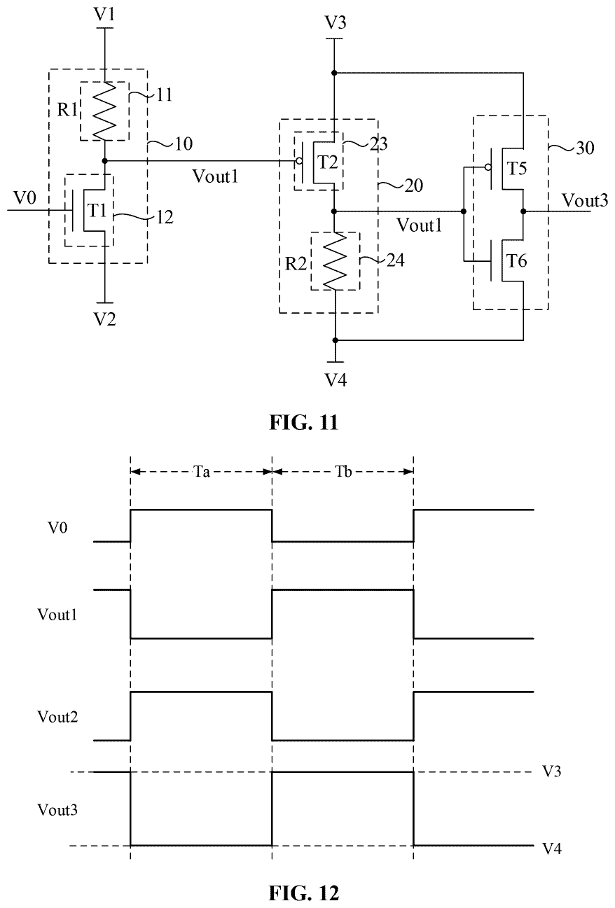

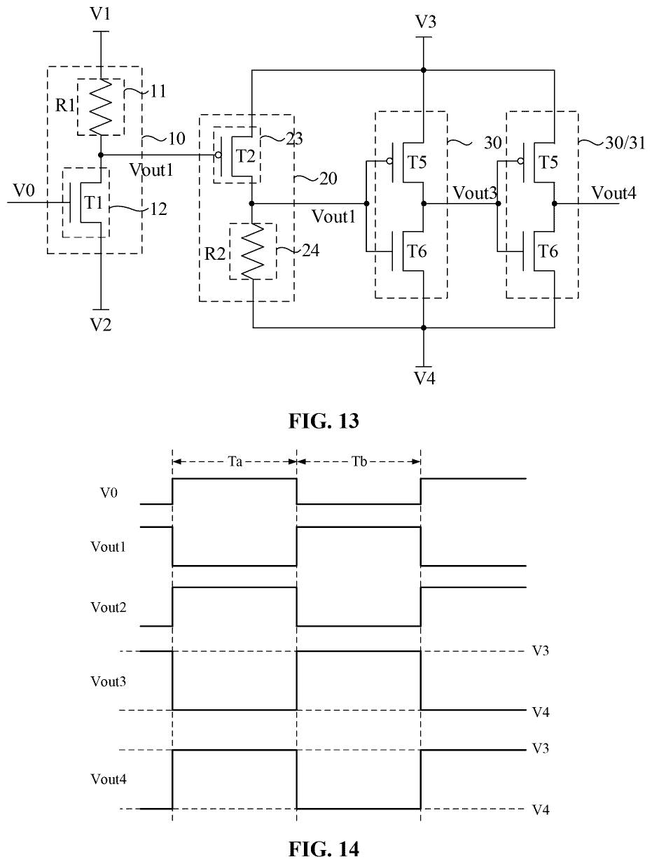

FIG. 11 is another structure diagram of a circuit structure according to an embodiment of the present disclosure, and FIG. 12 is a signal timing diagram of the circuit structure shown in FIG. 11. FIG. 13 is another structure diagram of a circuit structure according to an embodiment of the present disclosure, and FIG. 14 is a signal timing diagram of the circuit structure shown in FIG. 13. Referring to FIGS. 11 and 13, in one or more embodiments of the present disclosure, the circuit structure further includes N buffer branches 30, where N is a positive integer.

A control terminal of the first one of the N buffer branches 30 is connected to the second voltage division output terminal of the second voltage division branch 20, and when N≥2, a control terminal of an (i+1)-th buffer branch 30 is electrically connected to an output terminal of an i-th buffer branch 30 where i is an integer ranging from 1 to (N−1). Each buffer branch 30 includes a fifth transistor T5 and a sixth transistor T6, where the channel type of the fifth transistor T5 is different from that of the sixth transistor T6. A gate of the fifth transistor T5 is electrically connected to a gate of the sixth transistor T6 as a control terminal of each buffer branch 30. A first electrode of the fifth transistor T5 receives the third power signal V3, a second electrode of the fifth transistor T5 is electrically connected to a first electrode of the sixth transistor T6 as an output terminal of each buffer branch 30, and a second electrode of the sixth transistor T6 receives the fourth power signal V4.

In one or more embodiments, the circuit structure shown in FIG. 11 may include only one buffer branch 30. A connection node of the second electrode of the fifth transistor T5 and the first electrode of the sixth transistor T6 is not only an output terminal of the buffer branch 30 but also an output terminal of the entire circuit structure. In other embodiments, two or more buffer branches 30 may be disposed in the circuit structure. Only two buffer branches 30 disposed in the circuit structure are illustratively shown in FIG. 13. A control terminal of the first one of the N buffer branches 30 is connected to the second voltage division output terminal of the second voltage division branch 20. For each of the N buffer branches 30, a control terminal of a subsequent buffer branch 30 is connected to an output terminal of a previous buffer branch 30, and an output terminal of the last one of the N buffer branches 30 is the output terminal of the entire circuit structure.

In one or more embodiments, the buffer branch 30 can be treated as a gating unit. The control terminal of the buffer branch 30 is connected to the second voltage division output terminal of the second voltage division branch 20, that is, the buffer branch 30 is a structure that uses the output signal of the second voltage division branch 20 as a control signal to select and output different voltage signals. In one or more embodiments, the buffer branch 30 includes the fifth transistor T5 and the sixth transistor T6. One terminal of one of the two transistors is connected to one terminal of the other of the two transistors, and the other terminal of each of the two transistors is separately connected to a different power signal. The other terminal of the fifth transistor T5 receives the third power signal V3, and the other terminal of the sixth transistor T6 receives the fourth power signal V4. The two transistors are used as switch units which are controlled by the output signal of the second voltage division branch 20 to select and output the third power signal V3 or the fourth power signal V4. It is to be understood that the gate of the fifth transistor T5 and the gate of the sixth transistor T6 are connected to the second voltage division output terminal of the second voltage division branch 20, and the channel types of the fifth transistor T5 and the sixth transistor T6 are different, so that one of the two switch units is selected and turned on under the control of the same control signal, thereby gating and outputting the third power signal V3 or the fourth power signal V4.

With continued reference to FIG. 11, in one or more embodiments, the fifth transistor T5 is a P-type channel transistor, and the sixth transistor T6 is an N-type channel transistor. A working principle and working process of the circuit structure is described below by taking that the fifth transistor T5 is a P-type channel transistor, the sixth transistor T6 is an N-type channel transistor, the third power signal V3 is a VDD signal, and the fourth power signal V4 is a GND signal in the circuit structure shown in FIG. 11 as an example. Referring to FIGS. 4, 8, 11 and 12, at the first pulse level stage Ta, the first initial signal V0 is a high-level signal, and the output voltage of the second voltage division output terminal of the second voltage division branch 20 is R2×(V3−V4)/(R2+R_{T2_on}). At the second pulse level stage Tb, the first initial signal V0 is a low-level signal, and the output voltage of the second voltage division output terminal of the second voltage division branch 20 is slightly lower than the fourth power signal V4. The second voltage division output terminal outputs a high-level signal at the first pulse level stage Ta and outputs a low-level signal at the second pulse level stage Tb. Based on this, for the buffer branch 30, at the first pulse level stage Ta, the control terminal of the buffer branch 30 receives a high-level signal output by the second voltage division output terminal of the second voltage division branch 20, the fifth transistor T5 is turned off, the sixth transistor T6 is turned on, and the output terminal of the buffer branch 30 directly receives the fourth power signal V4 through the sixth transistor T6, and under the premise that an impedance of the sixth transistor T6 is not considered, the buffer branch 30 outputs the fourth power signal V4. At the second pulse level stage Tb, the control terminal of the buffer branch 30 receives a low-level signal output by the second voltage division output terminal of the second voltage division branch 20, the fifth transistor T5 is turned on, the sixth transistor T6 is turned off, and the output terminal of the buffer branch 30 directly receives the third power signal V3 through the fifth transistor T5, and under the premise that an impedance of the fifth transistor T5 is not considered, the buffer branch 30 outputs the third power signal V3.

It is to be understood from the working process and principle of the above circuit structure that in the circuit structure, the buffer branch 30 is added, two transistors of the buffer branch 30 are served as switch units, and one of the two switch units is selected and turned on so that the circuit structure can select and output the third power signal V3 or the fourth power signal V4 at different stages of the first initial signal V0 and a voltage of a final output signal of the circuit structure is separately and correspondingly adjusted to be consistent with the fourth power signal V4 and the third power signal V3 at the first pulse level stage Ta and the second pulse level stage Tb. For a circuit structure where no buffer branch 30 is disposed, the circuit structure shown in FIG. 4 is taken as an example. In the circuit structure, an internal resistance is generated due to the existence of threshold voltages in the first transistor T1 and the second transistor T2 so that the output voltage of the second voltage division output terminal of the second voltage division branch 20 at the first pulse level stage Ta is R2×(V3−V4)/(R2+R_{T2_on}), which cannot reach the third power signal V3. Moreover, since the transistor has characteristics of a capacitor, when the first initial signal V0 is switched between the first pulse level stage Ta and the second pulse level stage Tb, the second transistor T2 cannot be turned off in time, resulting in the generation of a leakage current, so that the second transistor T2 and the second resistor R2 are still in a series relationship and a delay of the output signal of the second voltage division output terminal of the second voltage division branch 20 is generated during the level switching. In comparison, according to the embodiments, in which the buffer branch 30 is added to the circuit structure, on the one hand, it can be ensured that voltages of two power signals are reached compared with an amplitude of the adjustment of the first initial signal V0. On the other hand, the delay of the output signal during the level switching can be avoided, thereby achieving a fast hop effect.

With continued reference to FIG. 13, in one or more embodiments, Nis an even number. As shown in an example in FIG. 13, N=2. Based on this, referring to FIG. 14, a working process and working principle of the circuit structure is described below. Similarly, it can be seen that the buffer circuit in the present embodiment is also served as a gating switch. Two transistors of the buffer circuit are served as two switch units, and one of the two switch units is selected and turned on. As can be seen from the working process of the circuit structure including one buffer branch 30 shown in FIGS. 11 and 12, at the first pulse level stage Ta, the sixth transistor T6 in the first one of the N buffer branches 30 is turned on, and the first one of the N buffer branches 30 outputs the fourth power signal V4, which may be understood as a low-level signal. At the second pulse level stage Tb, the fifth transistor T5 in the first one of the N buffer branches 30 is turned on, and the first one of the N buffer branches 30 outputs the third power signal V3, which may be understood as a high-level signal.

For the second one of the N buffer branches 30, the output signal of the first one of the N buffer branches 30 is a control signal of the second one of the N buffer branches 30. At the first pulse level stage Ta, a control terminal of the second one of the N buffer branches 30 receives the fourth power signal V4, that is, the low-level signal. In this case, in the second one of the N buffer branches 30, the fifth transistor T5 is turned on, the sixth transistor T6 is turned off, and the second one of the N buffer branches 30 outputs the third power signal V3. At the second pulse level stage Tb, the control terminal of the second one of the N buffer branches 30 receives the third power signal V3, that is, the high-level signal. In this case, in the second one of the N buffer branches 30, the fifth transistor T5 is turned off, the sixth transistor T6 is turned on, and the second one of the N buffer branches 30 outputs the fourth power signal V4.

As can be seen from a comparison between an output of the circuit structure including one stage of buffer branch 30 shown in FIG. 11 and an output of the circuit structure including two buffer branches 30 shown in FIG. 13, when the number of the N buffer branches 30 is an even number, that is, N is an even number, the final output signal of the circuit structure is a high level at the first pulse level stage Ta of the first initial signal V0 and is a low level at the second pulse level stage Tb of the first initial signal V0. That is, the final output signal and the first initial signal V0 have the same phase, regardless the final output signal and first initial signal V0 are high level, or the final output signal and first initial signal V0 are low level. In this way, the circuit structure only adjusts the amplitude of the voltage of the first initial signal V0 without changing the timing of the first initial signal V0, or changing the corresponding switch control logic based on the high level or the low level.

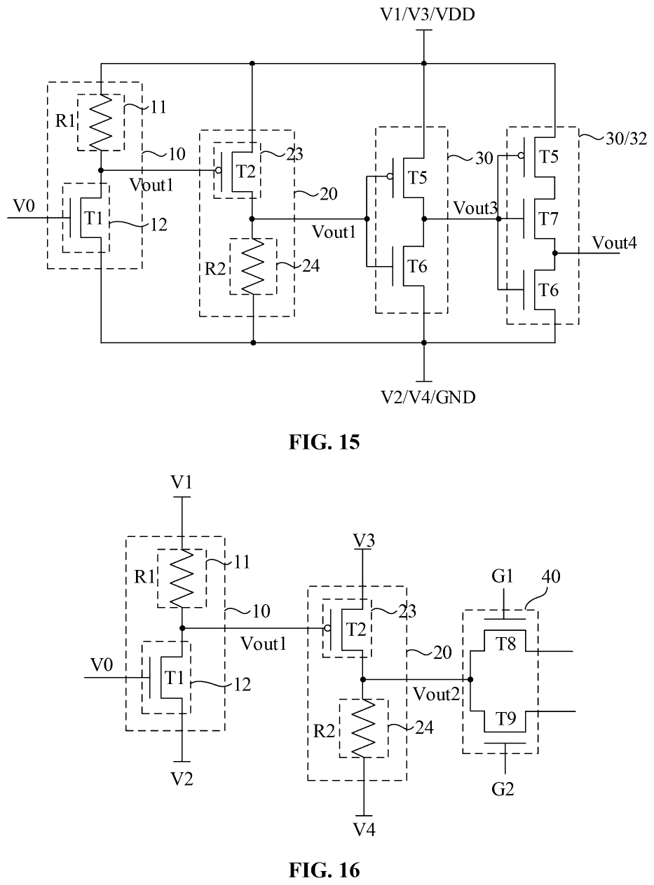

FIG. 15 is another structure diagram of a circuit structure according to an embodiment of the present disclosure. Referring to FIG. 15, in one or more embodiments, the N-th buffer branch 30 further includes a seventh transistor T7, where two electrodes of the seventh transistor T7 are connected to the fifth transistor T5 and the sixth transistor T6, respectively, and a gate of the seventh transistor T7 is electrically connected to the gate of the fifth transistor T5 and the gate of the sixth transistor T6. A connection node between the sixth transistor T6 and the seventh transistor T7 is served as an output terminal of the N-th buffer branch 30.

According to the present embodiment, a seventh transistor T7 is added to the N-th buffer branch 30, that is, the last buffer branch 30, to adjust the output voltage by using the seventh transistor T7. Since the seventh transistor T7 and the sixth transistor T6 have the same channel type and the gate of the sixth transistor T6 is electrically connected to the gate of the seventh transistor T7, when the sixth transistor T6 is turned on, the seventh transistor T7 is also turned on, and when the sixth transistor T6 is turned off, the seventh transistor T7 is also turned off. Therefore, the sixth transistor T6 and the seventh transistor T7 constitute a series voltage division branch. When the fifth transistor T5 is turned on, the sixth transistor T6 and the seventh transistor T7 are turned off, an output voltage Vdh of the connection node between the sixth transistor T6 and the seventh transistor T7 can be inferred on the basis of ignoring the resistance value of the fifth transistor T5 at the ON state, where Vdh=(V3−V4)×n/(n+1)+V4=V3×n/(n+1)−V4/(n+1), n is a ratio of a width-to-length ratio of the seventh transistor T7 to a width-to-length ratio of the sixth transistor T6. As can be seen, compared with the output signal of the circuit structure without the seventh transistor T7, the voltage difference is ΔV, where ΔV=V3−[V3×n/(n+1)−V4/(n+1)]=(V3+V4)/(n+1). As shown in FIG. 15, it is taken as an example that the third power signal V3 is a VDD signal and the fourth power signal V4 is a GND signal. An output voltage Vdh of the connection node between the sixth transistor T6 and the seventh transistor T7 can be inferred as that Vdh=VDD×n/(n+1). As can be seen, compared with the output signal of the circuit structure without the seventh transistor T7, the voltage difference is ΔV, where ΔV=VDD−Vdh=VDD/(n+1). As can be seen, by reasonably setting the value of n, a voltage value of a final output signal of the circuit structure can be adjusted based on the third power signal V3 and the fourth power signal V4 so that the voltage value can meet requirements of different application scenarios.

Further, In the present embodiment, N buffer branches 30 are disposed, and a seventh transistor T7 is added to the last buffer branch 30 so that a delay amount obtained when the buffer branch 30 controls the level hop of the output signal can be used, an amplitude range of the output signal can be adjusted by using the seventh transistor T7 and the circuit structure 30 can be flexibly applied to different scenarios, thereby increasing an applicable range of the circuit structure.

With continued reference to FIG. 15, further, width-to-length ratios of the sixth transistor T6 and the seventh transistor T7 may satisfy: W7/L7=n(W6/L6), and (V3+V4−5)/5≤n≤(V3+V4−2)/2, where n>0, W6 is a width of a channel of the sixth transistor T6, L6 is a length of the channel of the sixth transistor T6, W7 is a width of a channel of the seventh transistor T7, and L7 is a length of the channel of the seventh transistor T7.

As can be seen from the preceding inferences, compared with an output signal of a circuit structure without the seventh transistor T7, a voltage difference between the output signal of the circuit structure in the present embodiment and the output signal of the circuit structure without the seventh transistor T7 is ΔV=(V3+V4)/(n+1). A ratio n of the width-to-length ratio of the seventh transistor T7 to the width-to-length ratio of the sixth transistor T6 is limited within a range of (V3+V4−5)/5≤n≤(V3+V4−2)/2 so that ΔV may be controlled to be 2 V to 5 V. In this manner, the circuit structure in the present embodiment and the circuit structure without the seventh transistor T7 can be used in combination and separately to drive components such as transistors, circuits and devices with a voltage difference of 2 V to 5 V, thereby meeting different voltage requirements of particular application scenarios.

FIG. 16 is another structure diagram of a circuit structure according to an embodiment of the present disclosure. Referring to FIG. 16, in an embodiment of the present disclosure, a multiplexer 40 may be further disposed in the circuit structure, where the multiplexer 40 includes one input terminal and multiple output terminals, where the second voltage division output terminal is electrically connected to the one input terminal of the multiplexer 40.

In the present embodiment, by disposing the multiplexer 40 in the circuit structure, the output signals of the first voltage division branch 10 and the second voltage division branch 20 can be output from the multiple output terminals to drive multiple components, circuits and devices, thereby reducing the number of settings in the circuit structure. The multiplexer 40 may include multiple transistors. Gates of different transistors are connected to different control signals G. Under the control of the corresponding control signals G, the selection and output of the output signals from different output terminals can be implemented. For example, the multiplexer 40 in FIG. 16 includes only two transistors (an eighth transistor T8 and a ninth transistor T9), that is, two output terminals, and both of the transistors are P-type channel transistors. However, more than two transistors and a channel type of each of the more than two transistors may be set according to practical requirements, which is not limited herein.

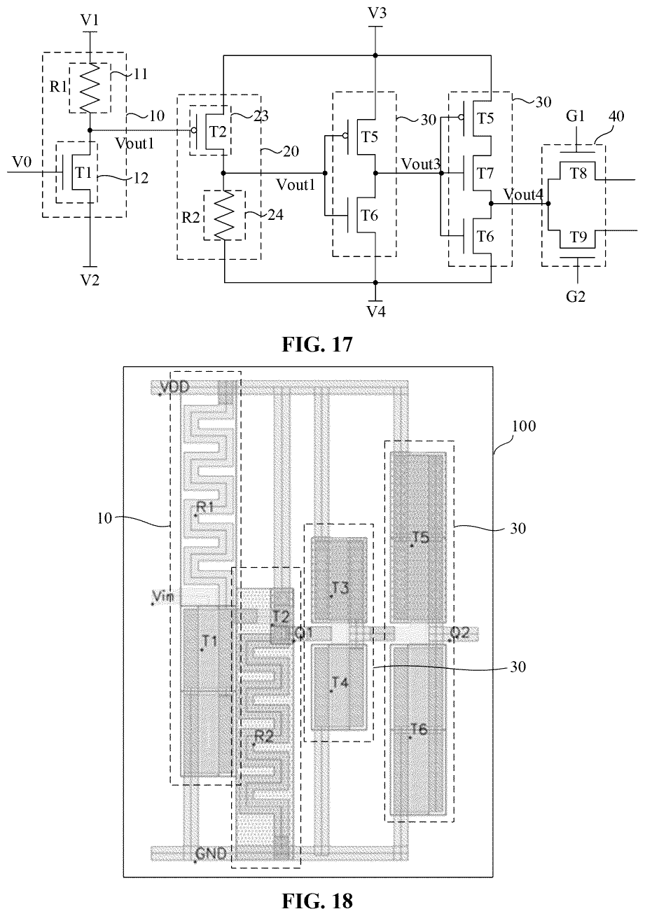

FIG. 17 is another structure diagram of a circuit structure according to an embodiment of the present disclosure. Referring to FIG. 17, in an embodiment of the present disclosure, the circuit structure further includes N buffer branches 30, where N is a positive integer. A control terminal of a first one of the N buffer branches 30 is connected to the second voltage division output terminal of the second voltage division branch 20, and when N≥2, a control terminal of an (i+1)-th buffer branch 30 is electrically connected to an output terminal of an i-th buffer branch 30, where i is an integer from 1 to (N−1). Each buffer branch 30 includes a fifth transistor T5 and a sixth transistor T6, where channel types of the fifth transistor T5 and the sixth transistor T6 are different. A gate of the fifth transistor T5 is electrically connected to a gate of the sixth transistor T6 as a control terminal of each buffer branch 30. A first electrode of the fifth transistor T5 receives the third power signal V3, a second electrode of the fifth transistor T5 is electrically connected to a first electrode of the sixth transistor T6 as an output terminal of each buffer branch 30, and a second electrode of the sixth transistor T6 receives the fourth power signal V4. The circuit structure further includes a multiplexer 40, where the multiplexer 40 includes one input terminal and multiple output terminals, where an output terminal of an N-th buffer branch 30 is electrically connected to the one input terminal of the multiplexer 40.

It is to be understood that, according to the embodiments, the N buffer branches 30 and the multiplexer 40 are both disposed in the circuit structure. By setting the N buffer branches 30, the amplitude of the output signal can be increased, and the delay during the level hop can be avoided. By setting the multiplexer 40 multiple outputs can be implemented, so that multiple components can be driven, and the number of driver circuits is reduced. The working process and principle of the N buffer branches 30 and the multiplexer 40 can refer to the preceding embodiments, which are not repeated herein.

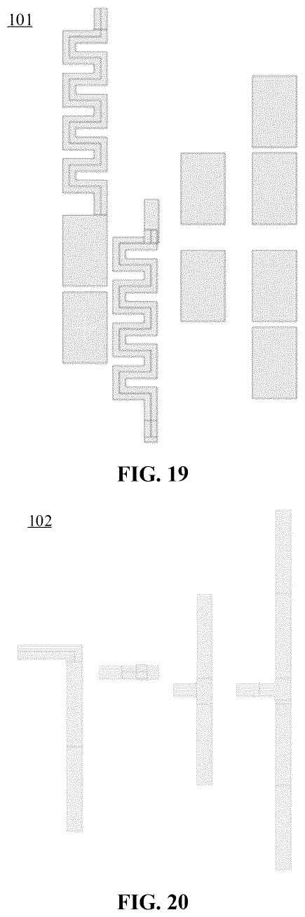

FIG. 18 is a layout diagram of the circuit structure shown in FIG. 13, and FIGS. 19 to 21 are structure diagrams of different films in the circuit structure shown in FIG. 18. Referring to FIG. 13 and FIGS. 18 to 21, in one or more embodiments, the circuit structure further includes a base substrate 100, where the first voltage division branch 10 and the second voltage division branch 20 are located on the same side of the base substrate 100. An orthographic projection of the first voltage division unit 11 on a plane where the base substrate 100 is located is adjacent to an orthographic projection of the second voltage division unit 12 on the plane where the base substrate 100 is located in a first direction, and an orthographic projection of the third voltage division unit 23 on the plane where the base substrate 100 is located is adjacent to an orthographic projection of the fourth voltage division unit 24 on the plane where the base substrate 100 is located in the first direction. An orthographic projection of a composite structure of the first voltage division unit 11 and the second voltage division unit 12 on the plane where the base substrate 100 is located is adjacent to an orthographic projection of a composite structure of the third voltage division unit 23 and the fourth voltage division unit 24 on the plane where the base substrate 100 is located in a second direction. The first direction and the second direction intersect with each other and are each parallel to the plane where the base substrate 100 is located.

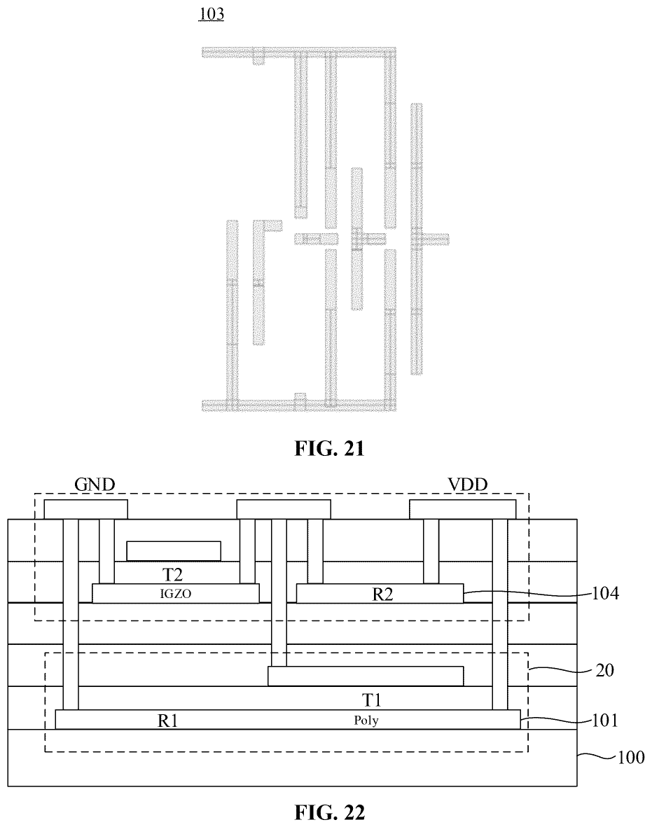

Based on the polysilicon layer 101 shown in FIG. 19, the polysilicon layer 101 can be prepared into the first voltage division unit 11, the second voltage division unit 12, the third voltage division unit 23 and the fourth voltage division unit 24 at different positions. The first voltage division unit 11 may be the first resistor R1 set by polysilicon wires. The second voltage division unit 12 may be the first transistor T1 formed by polysilicon wires, a gate layer 102 shown in FIG. 20 and a source-drain layer 103 shown in FIG. 21, where the gate layer 102 and the source-drain layer 103 are disposed in an upper layer of the polysilicon wires. The third voltage division unit 23 may be the second transistor T2 formed by polysilicon wires, a gate layer 102 shown in FIG. 20 and a source-drain layer 103 shown in FIG. 21, where the gate layer 102 and the source-drain layer 103 are disposed in an upper layer of the polysilicon wires. The fourth voltage division unit 24 may be the second resistor R2 set by polysilicon wires. In the present embodiment, the four voltage division units are disposed on the base substrate 100 in a tiled manner to ensure a compact layout of the entire circuit structure and avoid a too large occupation area, thereby contributing to the arrangement of the circuit structure in a practical application scenario and reducing the layout difficulty.

With continued reference to FIG. 13 and FIGS. 18 to 21, in one or more embodiments, a width-to-length ratio of a fifth transistor T5 in the (i+1)-th buffer branch 30 of the N buffer branches 30 is greater than a width-to-length ratio of a fifth transistor T5 in the i-th buffer branch 30 of the N buffer branches 30, and/or a width-to-length ratio of a sixth transistor T6 in the (i+1)-th buffer branch 30 of the N buffer branches 30 is greater than a width-to-length ratio of a sixth transistor T6 in the i-th buffer branch 30 of the N buffer branches 30, where N≥2.

According to the present embodiment, a subsequent transistor has a larger width-to-length ratio than a previous transistor. Increasing the width-to-length ratio of the channel of the transistor may be understood as reducing the resistance of the transistor. The larger width-to-length ratio of the transistor of the subsequent stage is, the smaller the resistance of the buffer branch 30 of the subsequent stage is, and the lower power consumption of the buffer branch 30 of the subsequent stage can be ensured. Moreover, it can be ensured that a transistor in the last buffer branch 30 has the largest width-to-length ratio and the smallest resistance so that a final output signal is separately closer to the third power signal V3 and the fourth power signal V4 at the two pulse level stages and a delay of the output signal during level hop can be better avoided.

FIG. 22 is a section view of the circuit structure shown in FIG. 10. Referring to FIGS. 10 and 22, in one or more embodiments, the circuit structure further includes a base substrate 100, where the first voltage division branch 10 and the second voltage division branch 20 are located on the same side of the base substrate 100. A film, where the second voltage division branch 20 is located, is located between the base substrate 100 and the film where the first voltage division branch 10 is located, in a direction perpendicular to a plane where the base substrate 100 is located. An orthographic projection of the first voltage division branch 10 on the plane where the base substrate 100 is located at least partially overlaps an orthographic projection of the second voltage division branch 20 on the plane where the base substrate 100 is located.

According to the present embodiment, the first voltage division branch 10 and the second voltage division branch 20 are laminated. The first transistor T1 is an N-type channel transistor, and a semiconductor layer of the first transistor T1 is formed by doping an indium gallium zinc oxide (IGZO) layer 104. The second transistor T2 is a P-type channel transistor, and a semiconductor layer of the second transistor T2 is formed by doping the polysilicon layer 101. The first resistor R1 in the first voltage division branch 10 may be made by the IGZO layer 104, and the second resistor R2 in the second voltage division branch 20 may be made by the polysilicon layer 101. As can be seen, since the IGZO layer 104 and the polysilicon layer 101 can be laminated on the base substrate 100, the first voltage division branch 10 and the second voltage division branch 20 can be laminated on the base substrate 100. In the present embodiment, the first voltage division branch 10 and the second voltage division branch 20 in the circuit structure are laminated on the base substrate 100 so that the projection of the first voltage division branch 10 overlaps the projection of the second voltage division branch 20, thereby effectively reducing an overall coverage area of the circuit structure, enabling the layout of the entire circuit structure to be more compact and avoiding a too large occupation area.

In the preceding two layout embodiments of the present disclosure, each of the first voltage division unit and/or the fourth voltage division unit includes a resistor, where an orthographic projection of the resistor on the plane where the base substrate is located extends in a zigzag manner.

With continued reference to FIGS. 18 and 19, both the first resistor R1 and the second resistor R2 may be in a zigzag shape. The zigzag manner of the resistor shown here is only an example rather than a limitation. A shape of a single zigzag portion may be set as an arc, a triangle, or the like, which is not limited herein. It is to be understood that setting the resistor to extend in the zigzag manner here can reduce the occupation area of the resistor as much as possible under the premise that an extension length is ensured, that is, a resistance value of the resistor is ensured, thereby compressing the entire circuit structure, increasing the compactness of the layout of the entire circuit structure and avoiding a too large occupation area.

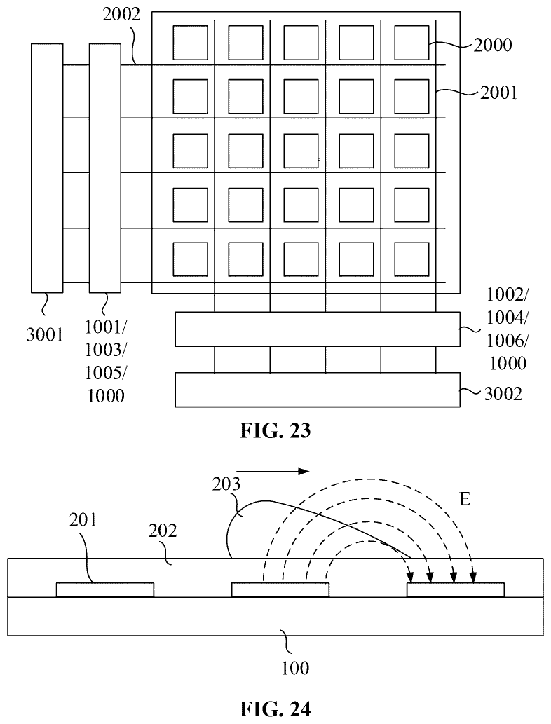

Embodiments of the present disclosure further provide a device. FIG. 23 is a structure diagram of a device according to an embodiment of the present disclosure. Referring to FIG. 23, the device includes the circuit structure 1000 provided in any one of the preceding embodiments. The device provided in the embodiments of the present disclosure has the corresponding beneficial effects of the circuit structure 1000 provided in the embodiments of the present disclosure, which are not repeated herein. For example, the device may be applied to the field of electrowetting technology, for example, the device may be a microfluidic device. In some embodiments, the device may also be applied to another field, for example, the device may also be an electronic-paper display device, which is not limited in the embodiments of the present disclosure.

For the microfluidic device, FIG. 24 is a structure diagram of electrowetting technology according to an embodiment of the present disclosure. Referring to FIG. 24, by electrowetting technologies, multiple drive electrodes 201 can be disposed on the base substrate 100, and covered by an insulating layer 202; when an electrowetting droplet 203 is dropped onto the insulating layer 202, a voltage is applied to the drive electrode 201 so that a driving electric field E is formed between adjacent drive electrodes 201 and the electrowetting droplet 203 can move. Moreover, the selection of the drive electrode 201 to which the voltage is applied can continuously drive the electrowetting droplet 203 so that the electrowetting droplet 203 reaches a set target position according to a set path.

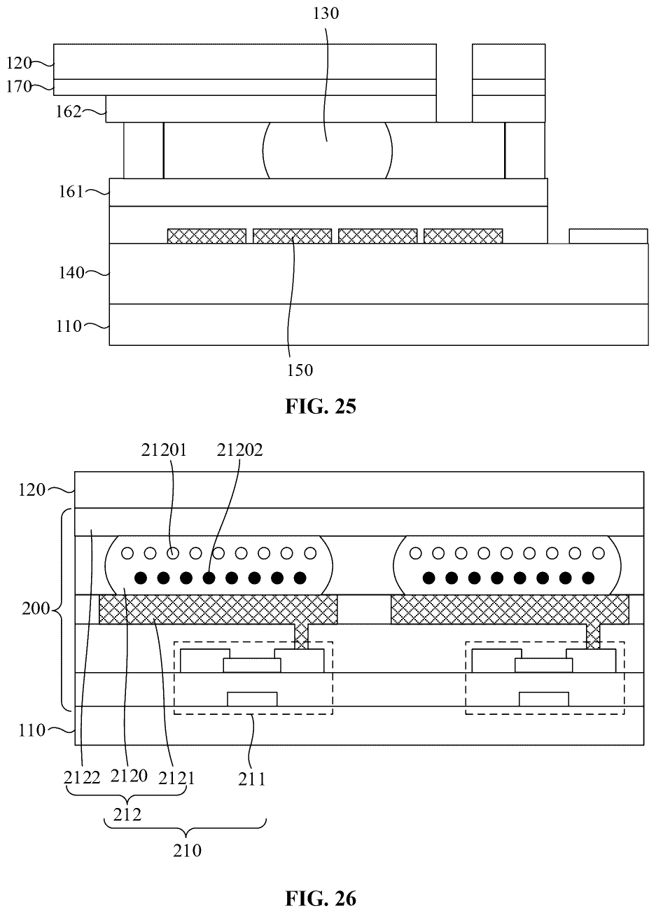

FIG. 25 is a section view of one pixel in a digital microfluidic device according to an embodiment of the present disclosure. Referring to FIG. 25, as can be seen from the section of the single pixel unit of the digital microfluidic device, the digital microfluidic device includes two substrates that are disposed above and below, respectively, and are disposed oppositely, that is, an upper substrate 120 and a lower substrate 110. A microdroplet 130 is accommodated between the two substrates. A first driver circuit 140, a pixel electrode 150 and a first hydrophobic layer 161 are disposed on a side of the lower substrate 110 facing the microdroplet 130, and a common electrode 170 and a second hydrophobic layer 162 are disposed on a side of the upper substrate 120 facing the microdroplet 130. The first driver circuit 140 applies a voltage to the pixel electrode 150, and at the same time, the common electrode 170 receives a common voltage. In this manner, an electric field is generated between the pixel electrode 150 and the common electrode 170 due to the existence of a voltage difference, and the microdroplet 130 can be driven by the electric field. However, on the one hand, since the microdroplet 130 is made of a material with relatively high viscosity in some application scenarios, the first driver circuit 140 needs to provide a higher drive voltage to the pixel electrode 150. On the other hand, since a composition of large-scale array active digital microfluidics generally needs a large number of pixel units, driving a large number of pixel units needs the digital microfluidic device to propose a requirement for a higher-level output voltage to a driver chip. However, the current driver chip cannot meet the above requirement for a high-level voltage, which causes that it is difficult to expand the application scenarios and is not easy to implement large-scale array active digital microfluidic driving and control.

As can be seen from the principle of the above electrowetting technology and the digital microfluidic device, the microfluidic device provided in the embodiments of the present disclosure and including any one of the circuit structures 1000 of the present disclosure can adjust a drive signal of the driver chip through the circuit structure so that the drive signal has a higher drive voltage, thereby providing a stronger electric field when the microdroplet is driven, effectively driving the microdroplet to move, achieving an effect of improving a drive capability of the driver chip, solving the problem that requirements for the large-scale array active digital microfluidic driving and control cannot be implemented due to an insufficient drive voltage in a current digital microfluidic field, enabling the drive signal to meet requirements for drive voltages of various microfluidic fields and expanding and enriching the application scenario of the microfluidic field.

For the electronic-paper display device, FIG. 26 is a section view of an electronic-paper display device according to an embodiment of the present disclosure. Referring to FIG. 26, the existing electronic-paper display device may include a lower substrate 110, an upper substrate 120, and an electrophoretic display layer 200 located between the lower substrate 110 and the upper substrate 120. The electrophoretic display layer 200 includes multiple electrophoretic pixels 210, where each of the multiple electrophoretic pixels 210 includes a second driver circuit 211 and a display element 212. The display element 212 includes a first electrode 2121, microcapsules 2120, and a second electrode 2122, where the first electrode 2121 is located on the side of the second electrode 2122 facing a light emission surface of the electronic-paper display device, the second electrode 2122 is electrically connected to the second driver circuit 211, and the microcapsules 2120 are located between the first electrode 2121 and the second electrode 2122. The microcapsules 2120 include two types of electrophoretic particles, one of which are white electrophoretic particles 21201, and the other of which are black electrophoretic particles 21202. For example, the white electrophoretic particles 21201 are positively charged, and the black electrophoretic particles 21202 are negatively charged.

When the electrophoretic pixel 210 is driven to display, the second driver circuit 211 provides a drive voltage to the first electrode 2121 and a drive voltage to the second electrode 2122, respectively, so that an electric field is formed between the first electrode 2121 and the second electrode 2122 to drive the electrophoretic particles to move. When a direction of the electric field points from the first electrode 2121 to the second electrode 2122, the positively charged white electrophoretic particle 21201 moves toward the second electrode 2122, that is, a position close a light emission side of the electronic-paper, and a position where the electrophoretic pixel 210 to which the microcapsules 2120 belongs is located is white. When the direction of the electric field points from the second electrode 2122 to the first electrode 2121, the negatively charged black electrophoretic particle 21202 moves toward the second electrode 2122, that is, the position close to the light emission side of the electronic-paper, and the position where the electrophoretic pixel 210 to which the microcapsules 2120 belongs is located is black. Electrophoretic particles of different colors in different microcapsules 2120 are controlled to move to the position close to the light emission side of the electronic-paper so that different colors are presented at different positions of the electronic-paper and complete image display is presented on the electronic-paper.

As can be seen from the structure and working principle of the above electronic-paper display device, the electronic-paper display device provided in the embodiments of the present disclosure and including any one of the circuit structures 1000 of the present disclosure can adjust a drive signal of a driver chip through the circuit structure 1000 so that the drive signal has a higher drive voltage, thereby providing a stronger electric field when the electrophoretic particles are driven, enabling the electrophoretic particles to response faster and more timely, improving the image refresh rate and fluency of the electronic-paper display device and improving the display effect of the electronic-paper display device.

Referring to FIG. 23, in one or more embodiments, in the device of the present disclosure, the circuit structure 1000 includes a first-type circuit structure 1001 and a second-type circuit structure 1002, where an output voltage of the first-type circuit structure 1001 at the first pulse level stage Ta is V11, and an output voltage of the second-type circuit structure 1002 at the first pulse level stage Ta is V21, where 2V≤|V11−V21|≤5V.

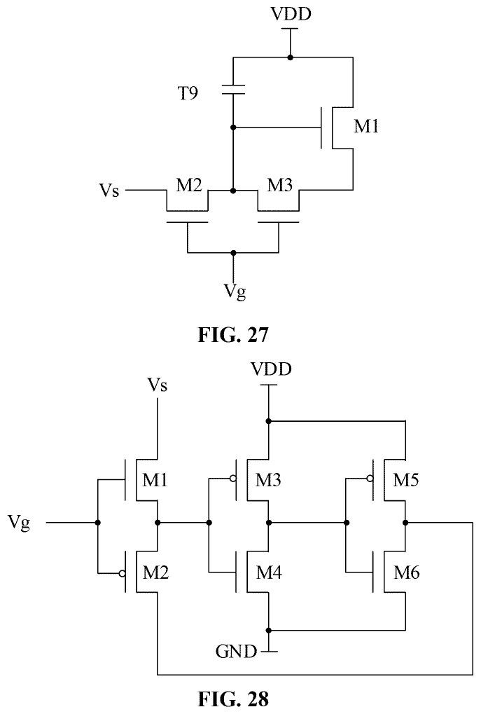

Taken the device shown in FIG. 23 being a microfluidic device as an example, the microfluidic device includes a working region AA, where multiple pixel units 2000 that are arranged in an array, multiple data lines 2001 and multiple scan lines 2002 are disposed in the microfluidic device. The data lines 2001 extend longitudinally and are electrically connected to the multiple pixel units 2000, and the scan lines 2002 extend horizontally and are electrically connected to the multiple pixel units 2000. In the present embodiment, the first-type circuit structure 1001 may be understood as being electrically connected to the scan line 2002 and providing a voltage signal to the scan line 2002, and the second-type circuit structure 1002 may be understood as being electrically connected to the data line 2001 and providing a voltage signal to the data line 2001. FIGS. 27 and 28 are structure diagrams of two driver circuits according to an embodiment of the present disclosure. Referring to FIGS. 27 and 28, a driver circuit 800 is disposed in the pixel unit 2000. The driver circuit 800 mainly includes a drive transistor M1, where the drive transistor M1 is generally a P-type channel transistor. The scan line 2002 is electrically connected to a gate of the drive transistor M1, and the data line 2001 is electrically connected to a source of the drive transistor M1. Under the premise that a gate voltage is provided to the drive transistor M1 by the first-type circuit structure 1001 and a source voltage is provided to the drive transistor M1 by the second-type circuit structure 1002, to control the drive transistor M1 to turn on, here, the gate voltage provided to the drive transistor M1 by the first-type circuit structure 1001 should be less than the source voltage provided to the drive transistor M1 by the second-type circuit structure 1002 with a voltage difference of 2 V to 5 V so that the P-type drive transistor M1 is effectively turned on, thereby turning on and addressing the corresponding pixel unit 2000. Of course, in practical application, the drive transistor M1 in the driver circuit 800 may also be an N-type channel transistor. On the contrary, to control the drive transistor M1 to turn on, here, the gate voltage provided to the drive transistor M1 by the first-type circuit structure 1001 should be greater than the source voltage provided to the drive transistor M1 by the second-type circuit structure 1002 with a voltage difference of 2 V to 5 V so that the N-type drive transistor M1 is effectively turned on, thereby turning on and addressing the corresponding pixel unit 2000.

Same as the embodiments of the circuit structure described above, in the embodiments of the device of the present disclosure, the circuit structure 1000 further includes a buffer branch 30, where a control terminal of the buffer branch 30 is electrically connected to the second voltage division output terminal of the second voltage division branch 20. The buffer branch 30 includes a first buffer subbranch 31 and a second buffer subbranch 32, where the number of transistors included in the first buffer subbranch 31 is greater than the number of transistors included in the second buffer subbranch 32. The circuit structure 1000 includes a third-type circuit structure 1003 and a fourth-type circuit structure 1004, where the third-type circuit structure 1003 includes the first buffer subbranch 31, and the fourth-type circuit structure 1004 includes the second buffer subbranch 32.

The buffer branch 30 in the circuit structure includes two types of buffer branches 30, that is, the first buffer subbranch 31 and the second buffer subbranch 32. The two types of buffer branches 30 are disposed in different circuit structures 1000, respectively, that is, the first buffer subbranch 31 is disposed in the third-type circuit structure 1003, and the second buffer subbranch 32 is disposed in the fourth-type circuit structure 1004. The two types of buffer branches differ mainly in the number of transistors. As can be seen related embodiments of the circuit structure, the circuit structure may include multiple buffer branches, or a seventh transistor T7 may also be added to the buffer branch, thereby implementing the difference in the number of transistors of the buffer branch and the difference in the buffer branch. The embodiment of the device indicates that in different circuit structures, buffer branches with different numbers of transistors can be used for implementing corresponding functions. The embodiment is described in detail below by using an embodiment.

It is taken as an example that the circuit structure shown in FIG. 13 includes the first buffer subbranch 31, the circuit structure shown in FIG. 15 includes the second buffer subbranch 32 and the device shown in FIG. 23 has the third-type circuit structure 1003 including the first buffer subbranch 31 and the fourth-type circuit structure 1004 including the second buffer subbranch 32. In an embodiment, each of the first buffer subbranch 31 and the second buffer subbranch 32 includes a fifth transistor T5 and a sixth transistor T6, where channel types of the fifth transistor T5 and the sixth transistor T6 are different. In the second buffer subbranch 32, a gate of the fifth transistor T5 is electrically connected to a gate of the sixth transistor T6 as a control terminal of the second buffer subbranch 32, a first electrode of the fifth transistor T5 receives the third power signal V3, a second electrode of the fifth transistor T5 is electrically connected to a first electrode of the sixth transistor T6 as an output terminal of the second buffer subbranch 32, and a second electrode of the sixth transistor T6 receives the fourth power signal V4. The first buffer subbranch 31 further includes a seventh transistor T7, where two electrodes of the seventh transistor T7 are connected to the fifth transistor T5 and the sixth transistor T6, respectively. In the first buffer subbranch 31, a gate of the fifth transistor T5, a gate of the seventh transistor T7 and a gate of the sixth transistor T6 are electrically connected as a control terminal of the first buffer subbranch 31, a first electrode of the fifth transistor T5 receives the third power signal V3, a connection node between the sixth transistor T6 and the seventh transistor T7 is used as an output terminal of the first buffer subbranch 31, and a second electrode of the sixth transistor T6 receives the fourth power signal V4.

Similarly, as described above, no seventh transistor T7 is disposed in the buffer branch, that is, the second buffer subbranch 32, of the circuit structure shown in FIG. 13, and the voltage of the output signal of the circuit structure at the first pulse level stage Ta is the third power signal V3. A seventh transistor T7 is disposed in the buffer branch, that is, the second buffer subbranch 32, of the circuit structure shown in FIG. 15, and the voltage of the output signal of the circuit structure at the first pulse level stage Ta is V3×n/(n+1)−V4/(n+1). The voltage difference between the two output signals is ΔV=V3−[V3×n/(n+1)−V4/(n+1)]=(V3+V4)/(n+1), where n is a ratio of the width-to-length ratio of the seventh transistor T7 to the width-to-length ratio of the sixth transistor T6. As can be seen, the two types of buffer branches are disposed differently. The seventh transistor T7 is added to the first buffer subbranch 31 so that the voltage of the output signal of the third-type circuit structure 1003 can be adjusted and is lower than the voltage of the output signal of the fourth-type circuit structure 1004 including the second buffer subbranch 32, and a voltage difference is between the voltage of the output signal of the third-type circuit structure 1003 and the voltage of the output signal of the fourth-type circuit structure 1004 including the second buffer subbranch 32. Moreover, the value of n is set reasonably, thereby controlling the range of the voltage difference ΔV. Similarly, as described above, (V3+V4−5)/5≤n≤(V3+V4−2)/2 may be set, where n>0, thereby controlling ΔV to be 2 V to 5 V. In this manner, the fourth-type circuit structure 1004 can be used for providing a relatively large source voltage to the drive transistor M1, and the third-type circuit structure 1003 can be used for providing a relatively small gate voltage to the drive transistor M1 with a voltage difference of 2 V to 5 V so that the P-type drive transistor M1 can be effectively turned on, thereby turning on and addressing the corresponding pixel unit 2000.

With continued reference to FIG. 23, in one or more embodiments, the device may further include a first chip 3001 and a second chip 3002. The circuit structure includes a fifth-type circuit structure 1005 and a sixth-type circuit structure 1006, where the first chip 3001 is electrically connected to the fifth-type circuit structure 1005 and provides an electric signal to a working region AA of the device through the fifth-type circuit structure 1005. The second chip 3002 is electrically connected to the sixth-type circuit structure 1006 and provides an electric signal to the working region AA of the device through the sixth-type circuit structure 1006.

Here, the first chip 3001 may be a gate driver chip, and the gate driver chip achieves a step-up effect through the voltage adjustment of the fifth-type circuit structure 1005, thereby providing a gate voltage signal with a relatively high amplitude to the driver circuit 800 in the working region. The second chip 3002 may be a source driver chip. Similarly, the gate driver chip achieves a step-up effect through the voltage adjustment of the sixth-type circuit structure 1006, thereby providing a source voltage signal with a relatively high amplitude to the driver circuit 800 in the working region.

It is to be noted that the preceding are preferred embodiments of the present disclosure and technical principles used therein. It is to be understood by those skilled in the art that the present disclosure is not limited to the embodiments described herein. Those skilled in the art can make various apparent modifications, adaptations, combinations and substitutions without departing from the scope of the present disclosure. Therefore, although the present disclosure has been described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A circuit structure, comprising a first voltage division branch and a second voltage division branch; wherein
a first terminal of the first voltage division branch receives a first power signal V1, a second terminal of the first voltage division branch receives a second power signal V2, a first terminal of the second voltage division branch receives a third power signal V3, and a second terminal of the second voltage division branch receives a fourth power signal V4, wherein V1>V2, and V3>V4;
the first voltage division branch comprises a first control terminal and a first voltage division output terminal, and the second voltage division branch comprises a second control terminal and a second voltage division output terminal, wherein the first control terminal receives a first initial signal V0, and the first voltage division output terminal is electrically connected to the second control terminal;
the first initial signal V0 comprises a first pulse level stage and a second pulse level stage; and
the first voltage division branch and the second voltage division branch are configured to perform the following operations:
at the first pulse level stage, outputting a first output level signal by the second voltage division output terminal under control of an output signal of the first voltage division output terminal; and
at the second pulse level stage, outputting a second output level signal by the second voltage division output terminal under the control of the output signal of the first voltage division output terminal, wherein the first output level signal and the second output level signal are different.

2. The circuit structure according to claim 1, wherein
the first voltage division branch comprises a first voltage division unit and a second voltage division unit, wherein a connection node between the first voltage division unit and the second voltage division unit is the first voltage division output terminal, at least one of the first voltage division unit or the second voltage division unit comprises the first control terminal; and
the second voltage division branch comprises a third voltage division unit and a fourth voltage division unit, wherein a connection node between the third voltage division unit and the fourth voltage division unit is the second voltage division output terminal, at least one of the third voltage division unit or the fourth voltage division unit comprises the second control terminal.

3. The circuit structure according to claim 2, wherein the first voltage division unit comprises a first resistor, and the second voltage division unit comprises a first transistor, wherein the first resistor satisfies at least one of: a resistance of the first resistor ranges from 10⁶Ω to 10⁸Ω, or, the first transistor is an N-type channel transistor;
wherein a first terminal of the first resistor receives the first power signal V1, a second terminal of the first resistor is electrically connected to a first electrode of the first transistor, and a second electrode of the first transistor receives the second power signal V2; and
wherein a gate of the first transistor is served as the first control terminal, and the gate of the first transistor receives the first initial signal V0.

4. The circuit structure according to claim 2, wherein the first voltage division unit comprises a third transistor, and the second voltage division unit comprises a first transistor, the first transistor is an N-type channel transistor, and the third transistor is a P-type channel transistor;
wherein a first electrode of the third transistor receives the first power signal V1, a second electrode of the third transistor is electrically connected to a first electrode of the first transistor, and a second electrode of the first transistor receives the second power signal V2; and
wherein a gate of the third transistor receives a reference voltage signal Vref, and a gate of the first transistor, as the first control terminal, receives the first initial signal V0;
wherein a voltage of the reference voltage signal Vref is lower than a threshold voltage of the third transistor; and
wherein the first transistor and the third transistor satisfy: R_{T1_on}<R_{T3}<R_{T1_off}, wherein R_{T1_on} is a resistance value of the first transistor in an ON state, R_{T1_off} is a resistance value of the first transistor in an OFF state, and R_{T3} is a resistance of the third transistor in a subthreshold state.

5. The circuit structure according to claim 2, wherein the third voltage division unit comprises a second transistor, and the fourth voltage division unit comprises a second resistor, wherein the second transistor satisfies at least one of: a resistance of the second resistor ranges from 10⁶Ω to 10⁸Ω, or the second transistor is a P-type channel transistor;
wherein a first electrode of the second transistor receives the third power signal V3, a second electrode of the second transistor is electrically connected to a first terminal of the second resistor, and a second terminal of the second resistor receives the fourth power signal V4; and
wherein a gate of the second transistor, as the second control terminal, is electrically connected to the first voltage division output terminal.

6. The circuit structure according to claim 2, wherein the third voltage division unit comprises a second transistor, and the fourth voltage division unit comprises a fourth transistor, wherein a channel type of the second transistor is different from a channel type of the fourth transistor, and the second transistor is a P-type channel transistor, and the fourth transistor is an N-type channel transistor;
wherein a first electrode of the second transistor receives the third power signal V3, a second electrode of the second transistor is electrically connected to a first electrode of the fourth transistor, and a second electrode of the fourth transistor receives the fourth power signal V4; and
wherein a gate of the second transistor is electrically connected to a gate of the fourth transistor, and the gate of the second transistor, as the second control terminal, is electrically connected to the first voltage division output terminal.

7. The circuit structure according to claim 1, wherein V1≥V3, and V2≤V4.

8. The circuit structure according to claim 2, wherein the circuit structure further comprises a base substrate, wherein the first voltage division branch and the second voltage division branch are located on a same side of the base substrate;
an orthographic projection of the first voltage division unit on a plane where the base substrate is located is adjacent to an orthographic projection of the second voltage division unit on the plane where the base substrate is located in a first direction, and an orthographic projection of the third voltage division unit on the plane where the base substrate is located is adjacent to an orthographic projection of the fourth voltage division unit on the plane where the base substrate is located in the first direction;
an orthographic projection of a composite structure of the first voltage division unit and the second voltage division unit on the plane where the base substrate is located is adjacent to an orthographic projection of a composite structure of the third voltage division unit and the fourth voltage division unit on the plane where the base substrate is located in a second direction; and
the first direction and the second direction intersect with each other and are both parallel to the plane where the base substrate is located; or,
wherein the circuit structure further comprises a base substrate,
wherein the first voltage division branch and the second voltage division branch are located on a same side of the base substrate,
wherein in a direction perpendicular to a plane where the base substrate is located, a film where the second voltage division branch is located is located between the base substrate and the film where the first voltage division branch is located, and an orthographic projection of the first voltage division branch on the plane where the base substrate is located at least partially overlaps an orthographic projection of the second voltage division branch on the plane where the base substrate is located.

9. The circuit structure according to claim 8, wherein at least one of the first voltage division unit or the fourth voltage division unit comprises a resistor, wherein an orthographic projection of the resistor on the plane where the base substrate is located extends in a zigzag manner.

10. The circuit structure according to claim 1, wherein the circuit structure comprises N buffer branches, wherein N is a positive integer, and N is an even number;
a control terminal of a first one of the N buffer branches is connected to the second voltage division output terminal of the second voltage division branch, and when N≥2, a control terminal of an (i+1)-th buffer branch of the N buffer branches is electrically connected to an output terminal of an i-th buffer branch the N buffer branches, wherein i is an integer ranging from 1 to (N−1);
each of the N buffer branches comprises a fifth transistor and a sixth transistor, wherein a channel type of the fifth transistor is different from a channel type of the sixth transistor;
a gate of the fifth transistor is electrically connected to a gate of the sixth transistor as a control terminal of each of the N buffer branches; and
a first electrode of the fifth transistor receives the third power signal V3, a second electrode of the fifth transistor is electrically connected to a first electrode of the sixth transistor as an output terminal of each of the N buffer branches, and a second electrode of the sixth transistor receives the fourth power signal V4.

11. The circuit structure according to claim 10, wherein a width-to-length ratio of a fifth transistor in the (i+1)-th buffer branch is greater than a width-to-length ratio of a fifth transistor in the i-th buffer branch, and/or a width-to-length ratio of a sixth transistor in the (i+1)-th buffer branch is greater than a width-to-length ratio of a sixth transistor in the i-th buffer branch, wherein N≥2.

12. The circuit structure according to claim 10, wherein the fifth transistor is a P-type channel transistor, and the sixth transistor is an N-type channel transistor.

13. The circuit structure according to claim 10, wherein an N-th buffer branch of the N buffer branches further comprises a seventh transistor, wherein two electrodes of the seventh transistor are connected to the fifth transistor and the sixth transistor, respectively, a gate of the seventh transistor is electrically connected to the gate of the fifth transistor and the gate of the sixth transistor, and a connection node between the sixth transistor and the seventh transistor is used as an output terminal of the N-th buffer branch.

14. The circuit structure according to claim 13, wherein width-to-length ratios of the sixth transistor and the seventh transistor satisfy: W7/L7=n(W6/L6), and (V3+V4−5)/5≤n≤(V3+V4−2)/2, wherein n>0; and
W6 is a width of a channel of the sixth transistor, L6 is a length of the channel of the sixth transistor, W7 is a width of a channel of the seventh transistor, and L7 is a length of the channel of the seventh transistor.

15. The circuit structure according to claim 13, further comprising a multiplexer, wherein the multiplexer comprises one input terminal and a plurality of output terminals, wherein the second voltage division output terminal is electrically connected to the one input terminal of the multiplexer.

16. A device, comprising a circuit structure, wherein the circuit structure comprises a first voltage division branch and a second voltage division branch; wherein
a first terminal of the first voltage division branch receives a first power signal V1, a second terminal of the first voltage division branch receives a second power signal V2, a first terminal of the second voltage division branch receives a third power signal V3, and a second terminal of the second voltage division branch receives a fourth power signal V4, wherein V1>V2, and V3>V4;
the first voltage division branch comprises a first control terminal and a first voltage division output terminal, and the second voltage division branch comprises a second control terminal and a second voltage division output terminal, wherein the first control terminal receives a first initial signal V0, and the first voltage division output terminal is electrically connected to the second control terminal;
the first initial signal V0 comprises a first pulse level stage and a second pulse level stage; and
the first voltage division branch and the second voltage division branch are configured to perform the following operations:
at the first pulse level stage, outputting a first output level signal by the second voltage division output terminal under control of an output signal of the first voltage division output terminal; and
at the second pulse level stage, outputting a second output level signal by the second voltage division output terminal under the control of the output signal of the first voltage division output terminal, wherein the first output level signal and the second output level signal are different.

17. The device according to claim 16, wherein the circuit structure comprises a first-type circuit structure and a second-type circuit structure; and
wherein an output voltage of the first-type circuit structure at the first pulse level stage is V11, and an output voltage of the second-type circuit structure at the first pulse level stage is V21, wherein 2V≤|V11−V21|≤5V.

18. The device according to claim 16, wherein the circuit structure further comprises a buffer branch;
wherein a control terminal of the buffer branch is electrically connected to the second voltage division output terminal of the second voltage division branch;
the buffer branch comprises a first buffer subbranch and a second buffer subbranch, wherein a number of transistors comprised in the first buffer subbranch is greater than a number of transistors comprised in the second buffer subbranch; and
the circuit structure comprises a third-type circuit structure and a fourth-type circuit structure, wherein the third-type circuit structure comprises the first buffer subbranch, and the fourth-type circuit structure comprises the second buffer subbranch.

19. The device according to claim 18, wherein each of the first buffer subbranch and the second buffer subbranch comprises a fifth transistor and a sixth transistor, wherein a channel type of the fifth transistor is different from a channel type of the sixth transistor;
in the second buffer subbranch, a gate of the fifth transistor is electrically connected to a gate of the sixth transistor as a control terminal of the second buffer subbranch, a first electrode of the fifth transistor receives the third power signal V3, a second electrode of the fifth transistor is electrically connected to a first electrode of the sixth transistor as an output terminal of the second buffer subbranch, and a second electrode of the sixth transistor receives the fourth power signal V4;
the first buffer subbranch further comprises a seventh transistor, wherein two electrodes of the seventh transistor are connected to the fifth transistor and the sixth transistor, respectively; and
in the first buffer subbranch, a gate of the fifth transistor, a gate of the seventh transistor and a gate of the sixth transistor are electrically connected as a control terminal of the first buffer subbranch, a first electrode of the fifth transistor receives the third power signal V3, a connection node between the sixth transistor and the seventh transistor is used as an output terminal of the first buffer subbranch, and a second electrode of the sixth transistor receives the fourth power signal V4.

20. The device according to claim 16, further comprising a first chip and a second chip;
wherein the circuit structure comprises a fifth-type circuit structure and a sixth-type circuit structure, and the first chip is electrically connected to the fifth-type circuit structure and provides an electric signal to a working region of the device through the fifth-type circuit structure; and
wherein the second chip is electrically connected to the sixth-type circuit structure and provides an electric signal to the working region of the device through the sixth-type circuit structure.
